(19) United States
(12) Patent Application Publication
(10) Pub. No.: US 2016/0190507 A1
(43) Pub. Date: Jun. 30, 2016

(54) AN ELECTRODE FOR AN ORGANIC ELECTRONIC DEVICE

(71) Applicant: CAMBRIDGE DISPLAY TECHNOLOGY LIMITED, Cambridgeshire (GB)

(72) Inventors: Alexander Doust, Cambridge (GB); Natasha M. J. Conway, Histon (GB); Colin Baker, Willingham (GB)

(73) Assignee: Cambridge Display Technology Limited, Godmanchester (GB)

(21) Appl. No.: 14/911,782

(22) PCT Filed: Aug. 13, 2014
(86) PCT No.: PCT/GB2014/052468

§ 371 Date: Feb. 12, 2016

(30) Foreign Application Priority Data
Aug. 13, 2013 (GB) 1314497.7

(51) Int. Cl. H01L 51/52; H01L 51/00; H01L 51/50

(52) U.S. Cl. CPC H01L 51/5221; H01L 51/5004; H01L 51/5088; H01L 51/0039; H01L 2251/552

(57) ABSTRACT

A layered structure for an organic electronic device comprising: •(i) a substrate; •(ii) an electrode deposited on said substrate; and •(iii) a hole injection layer (HIL) deposited on said electrode, wherein said electrode comprises a metal grid and an organic charge transporting polymer layer (CTL) which, together with said substrate, encapsulates said metal grid and protects it from being attacked by acidic species in the hole injection layer.

### FIELD OF THE INVENTION

The present invention relates to an electrode for an organic electronic device and to a layered structure comprising the electrode. The invention also relates to a method for making the electrode and the layered structure. Organic electronic devices comprising the electrode or layered structure and methods for making the devices also form a part of the invention.

### BACKGROUND

Organic electronic devices provide many potential advantages including inexpensive, low temperature, large scale fabrication on a variety of substrates including glass and plastic. Organic light emitting diode (OLED) displays provide additional advantages as compared with other display technologies—in particular they are bright, colourful, fast-switching and provide a wide viewing angle. OLED devices (which here include organometallic devices and devices including one or more phosphors) may be fabricated using either polymers or small molecules in a range of colours and in multi-coloured displays depending upon the materials used. For general background information reference may be made, for example, to WO90/13148, WO95/06400, WO99/48160 and U.S. Pat. No. 4,539,570, as well as to “Organic Light Emitting Materials and Devices” edited by Zhigang Li and Hong Meng, CRC Press (2007), ISBN 10: 1-57444-574X, which describes a number of materials and devices, both small molecule and polymer.

In its most basic form an OLED comprises a light emitting layer which is positioned in between an anode and a cathode. Frequently a hole injection layer is incorporated in between the anode and the light emitting layer. It functions to decrease the energy difference between the work function of the anode and the highest occupied molecular orbital (HOMO) of the light emitting layer thereby increasing the number of holes introduced into the light emitting layer. In operation holes are injected through the anode, and if present, the hole injection layer, into the light emitting layer and electrons are injected into the light emitting layer through the cathode. The holes and electrons combine in the light emitting layer to form an exciton which then undergoes radiative decay to provide light.

An important application of OLED technology is the development of white OLEDs. This requires a low cost anode architecture to make OLED lighting viable. This is a significant potential market (estimated to reach $6.3 billion by 2018). OLED lighting is a direct and viable competitor to existing technologies, particularly fluorescent lighting (whose lifetime can be shorter than advertised, can contain toxic materials including mercury and have practical inefficiencies due to fixture losses) and inorganic LEDs (which are good point sources of light but are not a good match for uniform, diffuse large area emission applications). OLED lighting is well suited to applications requiring uniform, diffuse large area emission.

A significant development is the introduction of OLED lighting tiles in which traditional anode materials such as ITO (indium tin oxide), gold or silver, all of which are relatively difficult to process and expensive, are replaced by photo-patternable anodes deposited from metal precursors (see, for example, WO2004/068389). This method of forming a conductive metal region on a substrate comprises depositing on the substrate a solution of a metal ion, and depositing on the substrate a solution of a reducing agent, such that the metal ion and the reducing agent react together in a reaction solution to form a conductive metal region on the substrate. Using this technique, it is possible to deposit grids or meshes of a metal on a substrate in a simple, cheap solution-processable way.

For low cost metals such as aluminium and especially copper, the ability to deposit grids of the order of sub 10 micron tracks on a substrate opens the door to the possibility of producing very flexible devices (contrast to ITO, which is brittle and can crack during processing) in which the fineness of the grid gives very high transparency to the anode. ITO also has a high resistivity, which creates problems for large area lighting panels, for example, due to the large voltage drops encountered towards the centre of the device, giving rise to a significant drop in light intensity. The metal tracks deposited by the method of WO2004/068389 produce a highly conductive surface without the voltage drops experienced with ITO devices.

The use of copper and other metals such as aluminium in the photo-patternable deposition technique of WO2004/068389 reduces cost both as a result of the replacement of expensive materials such as ITO and silver (and gold where transparency in not important) and because the electroless plating technique disclosed is simpler, cheaper and more efficient than the sputtering techniques typically used for ITO. This is particularly important in the development of low cost architecture for OLED lighting. The metal tracking (e.g. copper) is deposited by the solution-processable electroless plating technique on a transparent substrate (glass) and then the remaining layers are deposited using further solution-processable techniques as previously known in the art.

Other suitable techniques for the deposition of copper and other metals such as aluminium include vacuum deposition, printing, and photolithography.

However, there are problems with the use of metal tracking that is deposited using techniques such as electroless plating techniques, vacuum deposition or photolithography, especially preferred metals such as copper (which is both cheap and has a good conductivity) and aluminium. First, they oxidise readily. If an oxide layer develops on the metal surface then this increases the contact resistance between the metal and the hole injection layer that is deposited on it. This results in a reduction in the hole supply through the metal/hole injection layer interface, and hence reduces device efficiency. Second, hole injection layers comprise compounds such as PEDOT which are hydrophilic compounds which are deposited from aqueous solutions. As a consequence, it is not easy to deposit an aqueous solution of a hole injection compound on a metal surface. Third, many types of hole injection layers comprise acidic groups. PEDOT:PSS, for example, comprises sulphonic acid groups, which cause corrosion of the underlying metal surface and significantly reduce device lifetime.

Various attempts have been made to overcome these problems. For example the article by Harkema, S, et al. in Organic Light Emitting Materials and Devices XIII (Proc. of SPIE, Vol. 7415, 74150T, 2009) discloses ITO-free, flexible, white-emitting polymer-based OLEDs comprising a single layer of PEDOT:PSS that acts as both the anode and the hole injection layer. As a result, the need to deposit a separate hole injection layer is avoided. This approach does not, however, overcome the issue of corrosive reaction between acidic hole injection layers and underlying metal conductive tracks.

In another article by Choi S, et al. in Optics Express (4 Jul. 2011, vol 19, S4, A794) OLEDs are described which comprise a highly conductive PEDOT:PSS layer as a hole-injecting transparent electrode. It is combined with a thick metal grid structure comprising gold busbars and thick copper fingers. The gold busbars ensure good electrical contact with the PEDOT:PSS electrode whilst the copper fingers enable current to flow with low levels of potential drop across the device. The copper fingers are electrically insulated from the remainder of the device (i.e. other than from the gold busbars) by the presence of an insulating photoresist layer. This approach does not, however, avoid the use of gold, which is expensive, and because it is not possible to inject charge from the copper grid into the device, aperture ratio is lost without contributing to direct charge injection.

A need still exists for alternative technology that overcomes the above-described problems.

### SUMMARY OF INVENTION

Viewed from a first aspect the present invention provides a layered structure as specified in claim 1

Viewed from a further aspect the present invention provides an organic electronic device comprising a layered structure as specified in claim 1.

Viewed from a further aspect the present invention provides a method of making a layered structure as specified in claim 1.

### DEFINITIONS

As used herein the term “grid” refers to a mesh, network or framework of conductive tracks. Whilst sheets and foils are continuous forms, a grid is non-continuous since there are spaces in between the conductive tracks. Preferably the mesh, network or framework of the grid forms a pattern.

As used herein the term “visible light” refers to light having a wavelength of 380 to 740 nm.

As used herein the term “green light emitter” refers to a compound that emits radiation having a wavelength in the range 490 to 600 nm, preferably 490 to 560 nm.

As used herein the term “red light emitter” refers to a compound that emits radiation having a wavelength in the range 600 to 750 nm, preferably 635 to 700 nm.

As used herein the term “blue light emitter” refers to a compound that emits radiation having a wavelength of 450 to 490 nm.

As used herein the term “polymer” refers to a compound comprising repeating units. Polymers usually have a polydispersity of greater than 1.

As used herein the term “charge transporting polymer” refers to a polymer that can transport holes or electrons.

As used herein the term “cross linkable group” refers to a group comprising an unsaturated bond or a precursor capable of in situ formation of an unsaturated bond that can undergo a bond-forming reaction.

As used herein the term “alkyl” refers to saturated, straight chained, branched or cyclic groups. Alkyl groups may be substituted or unsubstituted.

As used herein the term “haloalkyl” refers to saturated, straight chained, branched or cyclic groups in which one or more hydrogen atoms are replaced by a halo atom, e.g. F or Cl, especially F.

As used herein, the term “cycloalkyl” refers to a saturated or partially saturated mono- or bicyclic alkyl ring system containing 3 to 10 carbon atoms. Cycloalkyl groups may be substituted or unsubstituted.

As used herein, the terms “heterocycloalkyl” and “heterocyclic” refers to a cycloalkyl group in which one or more ring carbon atoms are replaced by at least one hetero atom such as —O—, —N— or —S—. Heterocycloalkyl groups may be substituted or unsubstituted.

As used herein the term “alkenyl” refers to straight chained, branched or cyclic group comprising a double bond. Alkenyl groups may be substituted or unsubstituted.

As used herein the term “alkynyl” refers to straight chained, branched or cyclic groups comprising a triple bond. Alkynyl groups may be substituted or unsubstituted.

Optional substituents that may be present on alkyl, cycloalkyl, heterocycloalkyl, alkenyl and alkynyl groups as well as the alkyl moiety of an arylalkyl group include C₁₋₁₆ alkyl or C₁₋₁₆ cycloalkyl wherein one or more non-adjacent C atoms may be replaced with O, S, N, C═O and —COO—, substituted or unsubstituted C₅₋₁₄ aryl, substituted or unsubstituted C₅₋₁₄ heteroaryl, C₁₋₁₆ alkoxy, C₁₋₁₆ alkylthio, halo, e.g. fluorine and chlorine, cyano and arylalkyl.

As used herein, the term “aryl” refers to a group comprising at least one aromatic ring. The term aryl encompasses heteroaryl as well as fused ring systems wherein one or more aromatic ring is fused to a cycloalkyl ring. Aryl groups may be substituted or unsubstituted.

As used herein, the term “heteroaryl” refers to a group comprising at least one aromatic ring in which one or more ring carbon atoms are replaced by at least one hetero atom such as —O—, —N— or —S—.

Optional substituents that may be present on aryl or heteroaryl groups as well as the aryl moiety of arylalkyl groups include halide, cyano, C₁₋₁₆ alkyl, C₁₋₁₆ fluoroalkyl, C₁₋₁₆ alkoxy, C₁₋₁₆ fluoroalkoxy, C₅₋₁₄ aryl and C₅₋₁₄ heteroaryl.

As used herein, the term “arylalkyl” refers to an alkyl group as hereinbefore defined that is substituted with an aryl group as hereinbefore defined.

As used herein, the term “heteroarylalkyl” refers to an alkyl group as hereinbefore defined that is substituted with a heteroaryl group as hereinbefore defined.

As used herein the term “halogen” encompasses atoms selected from the group consisting of F, Cl, Br and I.

As used herein the term “alkoxy” refers to O-alkyl groups, wherein alkyl is as defined above.

As used herein the term “aryloxy” refers to O-aryl groups, wherein aryl is as defined above.

As used herein the term “arylalkoxy” refers to O-arylalkyl groups, wherein arylalkyl is as defined above.

As used herein the term “alkylthio” refers to S-alkyl groups, wherein alkyl is as defined above.

As used herein the term “arylthio” refers to S-aryl groups, wherein aryl is as defined above.

As used herein the term “arylalkylthio” refers to S-arylalkyl groups, wherein arylalkyl are as defined above.

### DESCRIPTION OF THE INVENTION

The electrode of the present invention comprises a metal grid and an organic charge transporting polymer layer on at least one surface of the metal grid. The electrode is preferably used in an organic electronic device as a cathode or an anode and more preferably as an anode. The presence of the organic charge transporting polymer layer on the surface of the metal grid advantageously protects the metal from overlying layers such as acidic hole injection layers. The organic charge transporting polymer layer preferably forms a protective layer or a capping layer on the metal comprising the electrode. Preferably the organic charge transporting polymer layer protects the underlying metal from corrosion. As a result the electrical performance of devices comprising an electrode, e.g. anode, of the present invention is significantly improved compared to devices comprising conventional anodes solely comprising reactive or oxidising metal(s).

In the electrodes of the present invention the organic charge transporting polymer is present as a layer on at least one surface of the metal grid. More preferably the organic charge transporting polymer is present as a layer on all exposed surfaces of the metal grid. Preferably the electrode further comprises a substrate. Preferably the metal grid comprising the electrode is deposited on the substrate. Preferably therefore the organic charge transporting polymer is present as a layer on the metal grid and, where the grid is not present, as a layer on the substrate. Preferably the organic charge transporting polymer, together with a substrate, encapsulates the metal grid.

The electrodes of the present invention comprise a metal grid. The grid comprises conductive metal tracks. The use of a grid enables a sufficient level of conductivity to be achieved uniformly over large surface areas, e.g. in the order of 100 to 1000 cm². The metal grid preferably forms a pattern of hexagons and more preferably forms a honeycomb pattern. More preferably the metal grid forms a pattern of hexagons wherein each side of each hexagon is shared by two hexagons. Still more preferably the metal grid forms a pattern of hexagons wherein each corner of each hexagon is shared by three hexagons. Yet more preferably the metal grid forms a pattern of hexagons wherein each side of each hexagon is shared by two hexagons and each corner of each hexagon is shared by three hexagons. Obviously, however, those hexagons present at the edges of the grid do not meet these requirements. Another preferred metal grid is described in WO2012/004552, the entire contents of which are incorporated herein by reference.

In preferred metal grids of the present invention the conductive track has a width of 10 to 100 microns, more preferably 25 to 70 microns and yet more preferably 30 to 50 microns. In further preferred metal grids of the present invention the conductive track has a height of 100 to 500 nm, more preferably 200 to 350 nm and yet more preferably about 250 nm. In further preferred metal grids of the present invention forming a pattern of hexagons, the distance between conductive track forming parallel sides of each hexagon is 300 to 1000 microns, more preferably 400 to 750 microns and yet more preferably about 540 microns. Yet further preferred grids of the present invention have a sheet resistance of less than 5 Ohms/sq, more preferably less than 2 Ohms/sq and still more preferably less than 1 Ohm/sq. Still further preferred grids of the invention have a transmission of greater than 80%, more preferably greater than 90% and still more preferably greater than 95%.

The electrodes of the present invention are preferably transparent to visible light, i.e. light having a wavelength of 380 to 740 nm. This allows the electrodes of the present invention to be employed in, for example, lighting tiles.

In preferred electrodes of the present invention the metal is a metal that forms resistive oxides. Representative examples of metals that may be present in the metals of the present invention include copper, aluminium, titanium, tantalum, molybdenum or steel. Preferably the metal is copper. Copper is preferred as it is highly conductive and is cheap.

The organic charge transporting polymer layer present in the electrode of the present invention is preferably a hole transporting polymer. This layer acts as a barrier between the overlying layer, e.g. an acidic hole injection layer, and the underlying metal grid. The organic charge transporting polymer layer therefore prevents the copper from undergoing oxidation due to contact with an acidic layer. Critically, however, the organic charge transporting layer is also an excellent charge, e.g. hole, transporter so that the conductivity of the electrode is not compromised by its presence.

Preferably the organic charge transporting polymer layer is deposited from solution. Any conventional solution-based processing method may be used. Representative examples of solution-based processing methods include spin coating, gravure printing, flexographic printing, dip coating, slot die coating, doctor blade coating and ink-jet printing. In some preferred methods, depositing is by spin coating or ink jet printing. The parameters used for spin coating the charge transporting polymer layer such as spin coating speed, acceleration and time are selected on the basis of the target thickness for the layer.

Preferably the organic charge transporting polymer is deposited from a solution comprising an aromatic solvent and still more preferably an anhydrous aromatic solvent. This is advantageous as it minimises the amount of water present in the resulting device which, in turn, minimises the potential for corrosive reaction between metal, water and acidic hole injection layer. Preferably the aromatic solvent is selected from a substituted benzene, a substituted naphthalene, a substituted tetrahydronaphthalene or a substituted or unsubstituted C₅₋₈ cycloalkylbenzene. Suitable aromatic solvents are commercially available from a range of suppliers.

Particularly preferably the aromatic solvent is selected from the group consisting of toluene, o-xylene, m-xylene, p-xylene, anisole (or methoxybenzene), mesitylene, ethoxybenzene, 2-methylanisole, 3-methylanisole, 4-methylanisole, 1-ethoxy-2-methylbenzene, 1-ethoxy-3-methylbenzene, 1-ethoxy-4-methylbenzene, acetophenone, tetralin, 1,2-dimethoxybenzene, 1,3-dimethoxybenzene, 1,4-dimethoxybenzene, 1-methoxy-2-ethoxybenzene, 1-methoxy-3-ethoxybenzene, 1-methoxy-4-ethoxybenzene, ethyl benzoate, 1,2-diethoxybenzene, 2-methyl acetophenone, 3-methylacetophenone, 4-methylacetophenone, 2-ethylacetophenone, 3-ethylacetophenone, 4-ethylacetophenone, 1,3-diethoxybenzene, 1,4-diethoxybenzene, 2-methoxyacetophenone, 3-methoxyacetophenone, 4-methoxyacetophenone, ethyl 2-methylbenzoate, ethyl 3-methylbenzoate, ethyl 4-methylbenzoate, ethyl 2-ethylbenzoate, ethyl 3-ethylbenzoate, ethyl 4-ethylbenzoate, 1-methylnaphthalene and cyclohexylbenzene. Particularly preferably the aromatic solvent is selected from the group consisting of toluene, o-xylene, m-xylene, p-xylene, anisole (or methoxybenzene), mesitylene and tetralin.

Preferably the organic charge transporting polymer layer comprises at least two different monomers and more preferably at least three different monomers. Still more preferably the organic charge transporting polymer layer comprises three, four or five different monomers.

Preferably the organic charge transporting polymer layer comprises at least one repeat unit comprising an amine group. This is advantageous as the presence of amine groups improves the supply of holes within the polymer structure and therefore its hole transporting ability. Preferably the organic charge transporting polymer comprises at least one repeat unit comprising an amine group selected from formulae (Ai) or (Aii) shown below:

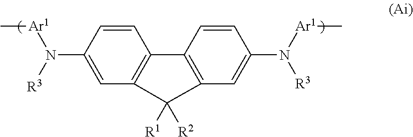

wherein R¹ and R² are independently selected from hydrogen or unsubstituted or substituted C₁₋₁₆ alkyl wherein one or more non-adjacent C atoms may be replaced with O, S, N, CO and —COO—, C₁₋₁₆ alkoxy, C₅₋₁₄ aryl, arylalkyl, C₅₋₁₄ heteroaryl and heteroarylalkyl; and R³ and Ar¹ are independently selected from unsubstituted or substituted C₅₋₁₄ aryl or unsubstituted or substituted C₅₋₁₄ heteroaryl;

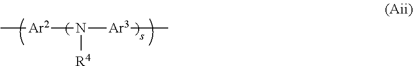

wherein Ar² and Ar³ are unsubstituted or substituted C₅₋₁₄ aryl or C₅₋₁₄ heteroaryl groups, s is greater than or equal to 1, and R⁴ is H or a substituent selected from C₁₋₁₆ alkyl, C₅₋₁₄ aryl or C₅₋₁₄ heteroaryl. Any of the aryl or heteroaryl groups in the unit of formula (Aii) may be substituted. Preferred substituents include C₁₋₁₆ alkyl and C₁₋₁₆ alkoxy groups. Any of the aryl or heteroaryl groups in the repeat unit of Formula (Aii) may be linked by a direct bond or a divalent linking atom or group. Preferred divalent linking atoms and groups include O, S, substituted N and substituted C.

In preferred repeat units of formula (Ai) R¹ and R² are the same. In particularly preferred repeat units at least one and more preferably both of R¹ and R² comprise hydrogen or unsubstituted or substituted C₁₋₁₆ alkyl wherein one or more non-adjacent C atoms may be replaced with O, S, N, CO and —COO—, C₁₋₁₆ alkoxy, C₅₋₁₄ aryl, arylalkyl, C₅₋₁₄ heteroaryl and heteroarylalkyl. Particularly preferably Wand R² comprise C₁₋₁₆ alkyl, especially C₁₋₁₆ unsubstituted alkyl.

In further preferred repeat units of formula (Ai), R³ is unsubstituted or substituted C₅₋₁₄ aryl, more preferably C₁₋₆ alkyl substituted C₅₋₁₄ aryl (e.g. phenyl) and especially preferably toluyl.

In further preferred repeat units of formula (Ai), Ar¹ is unsubstituted or substituted C₅₋₁₄ aryl and more preferably unsubstituted C₅₋₁₄ aryl and especially preferably phenyl.

A particularly preferred repeat unit of formula (Ai) is shown below.

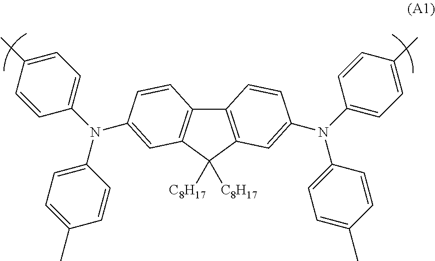

Repeat units of formula (Ai) may be incorporated into charge transporting polymers using monomers described in WO2005/049546.

Particularly preferred repeat units of formula (Aii) are those of formula (Aiii) or (Aiv) shown below.

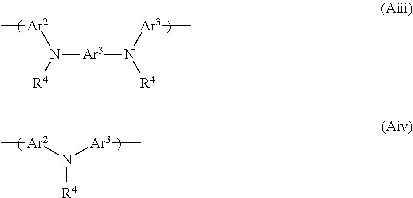

wherein Ar², Ar³ and R⁴ are as defined above.

In preferred units of formula (Aiii) and (Aiv) Ar² and Ar³ are the same. In particularly preferred repeat units Ar² and Ar³ comprise substituted or unsubstituted C₅₋₁₄ aryl. When present, preferred substituents for Ar² and Ar³ include C₁₋₁₆ alkyl and C₁₋₁₆ alkoxy groups. Especially preferred Ar² and Ar³ groups are unsubstituted C₆ aryl.

In further preferred repeat units of formula (Aiii) and (Aiv), R⁴ comprises substituted or unsubstituted C₆₋₁₄ aryl. When present, preferred substituents for aryl include straight chain or branched C₁₋₁₆ alkyl and C₁₋₁₆ alkoxy groups. Preferably R⁴ is substituted, particularly preferably by a C₁₋₁₆ alkyl, more preferably C₁₋₆ alkyl. In repeat unit of formula (Aiii) preferred substituents are strain chained alkyl. In preferred repeat units of formula (Aiv) preferred substituents are branched C₂₋₆ alkyl groups.

Two particularly preferred repeat units of formula (Aiii) is shown below:

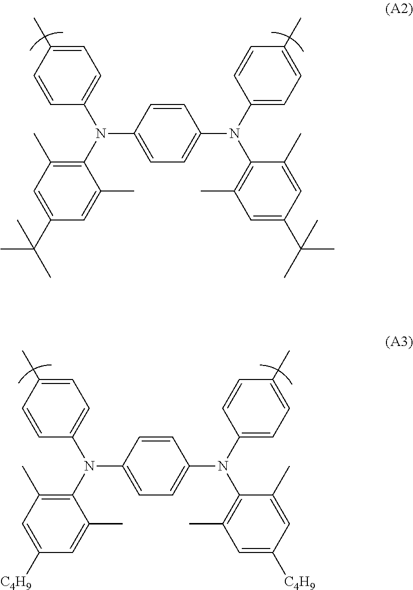

A particularly preferred repeat unit of formula (Aiv) is shown below:

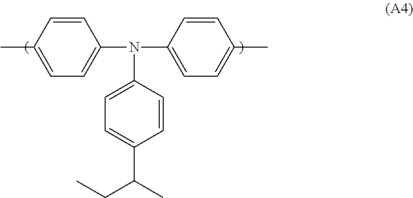

Repeat units of formula (Aii) may be incorporated into charge transporting polymers using monomers as described in WO99/54385, WO2008/016090, WO2008/111658, WO2009/110642 and WO2010/013724.

Preferably the organic charge transporting polymer layer comprises at least one repeat unit comprising a cross-linkable group. Preferably the at least one repeat unit comprising a cross-linkable group is selected from formulae (Bi) or (Bii):

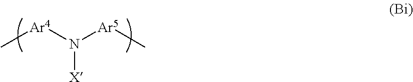

wherein Ar⁴ and Ar⁵ represent C₅₋₁₄ aryl or C₅₋₁₄ heteroaryl and X′ is a cross-linkable group;

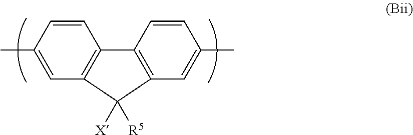

wherein X′ is a cross-linkable group and R⁵ is independently selected from X′, hydrogen, unsubstituted or substituted C₁₋₁₆ alkyl, wherein one or more non-adjacent C atoms may be replaced with O, S, N, CO and —COO—, unsubstituted or substituted C₁₋₁₆ alkenyl, unsubstituted or substituted C₁₋₁₆ alkoxy, optionally substituted C₅₋₁₄ aryl, unsubstituted or substituted arylalkyl, unsubstituted or substituted C₅₋₁₄ heteroaryl and unsubstituted or substituted heteroarylalkyl.

In preferred units of formula (Bi) Ar⁴ and Ar⁵ are the same. In particularly preferred repeat units Ar⁴ and Ar⁵ comprise substituted or unsubstituted C₅₋₁₄ aryl. When present, preferred substituents for Ar⁴ and Ar⁵ include C₁₋₁₆ alkyl and C₁₋₁₆ alkoxy groups. Especially preferred Ar⁴ and Ar⁵ groups are unsubstituted C₆ aryl.

Examples of cross-linkable group X′ in repeat unit (Bi) include moieties containing a double bond, a triple bond, a precursor capable of in situ formation of a double bond, or an unsaturated heterocyclic group. In some preferred repeat units of formula (Bi) the cross-linkable group X′ contains a precursor capable of in situ formation of a double bond. More preferably X′ contains a benzocyclobutanyl group. Especially preferred X′ groups comprise a C₅₋₁₂ aryl group substituted with a benzocyclobutanyl group, particularly preferably C₆ aryl substituted with a benzocyclobutanyl group.

A particularly preferred repeat unit of formula (Bi) is shown below:

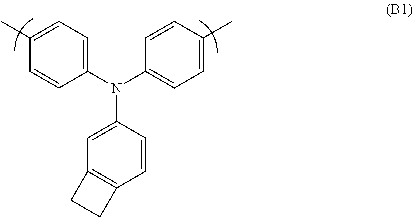

Repeat units of formula (Bi) may be incorporated into charge transporting polymers using monomers as described in WO2005/052027.

In preferred repeat units of formula (Bii) X′ is a double bond, a triple bond, a precursor capable of in situ formation of a double bond, or an unsaturated heterocyclic group. In some preferred repeat units of formula (Bii) the cross-linkable group X′ is contains a double bond or is a precursor capable of in situ formation of a double bond. More preferably X′ contains —CH═CH₂ group or a benzocyclobutanyl group. Especially preferred X′ groups comprise a C₁₋₁₆ alkylidene group or a C₅₋₁₂ aryl group substituted with a benzocyclobutanyl group, particularly preferably C₆ aryl substituted with a benzocyclobutanyl group.

In preferred repeat units of formula (Bii) R⁵ is X′. Still more preferably X′ and R⁵ are identical.

Two particularly preferred repeat units of formula (Bii) are shown below:

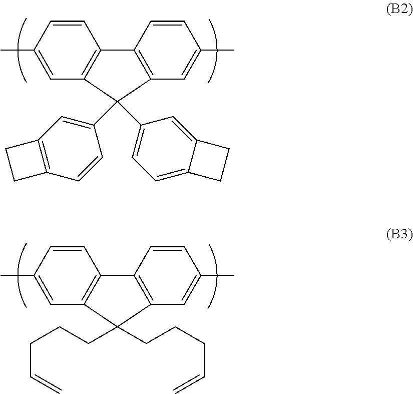

Repeat units of formula (Bii) may be incorporated into charge transporting polymers using monomers as described in WO2002/092723.

Preferably the organic charge transporting polymer layer of the present invention comprises at least one repeat unit selected from formula (C) below:

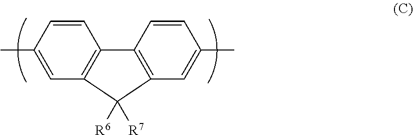

wherein R⁶ and R⁷ are independently selected from hydrogen, unsubstituted or substituted C₁₋₁₆ alkyl, wherein one or more non-adjacent C atoms may be replaced with O, S, N, CO and —COO—, unsubstituted or substituted C₁₋₁₆ alkoxy, unsubstituted or substituted C₅₋₁₄ aryl, unsubstituted or substituted arylalkyl, unsubstituted or substituted C₅₋₁₄ heteroaryl and unsubstituted or substituted heteroarylalkyl. Optional substituents are preferably selected from the group consisting of C₁₋₁₆ alkyl or C₁₋₁₆ cycloalkyl wherein one or more non-adjacent C atoms may be replaced with O, S, N, C═O and —COO—, unsubstituted or substituted C₅₋₁₄ aryl, unsubstituted or substituted C₅₋₁₄ heteroaryl, C₁₋₁₆ alkoxy, C₁₋₁₆ alkylthio, fluorine, cyano and arylalkyl.

In preferred repeat units of formula (C) R⁶ and R⁷ are the same. In particularly preferred repeat units at least one and more preferably both of R⁶ and R⁷ comprise an unsubstituted or substituted C₁₋₁₆ alkyl or an unsubstituted or substituted C₅₋₁₄ aryl, e.g. a C₆ aryl. Preferred substituents of aryl groups are C₁₋₁₆ alkyl and still more preferably an unsubstituted C₁₋₁₆ alkyl group.

Particularly preferred repeat units of formula (C) are shown below:

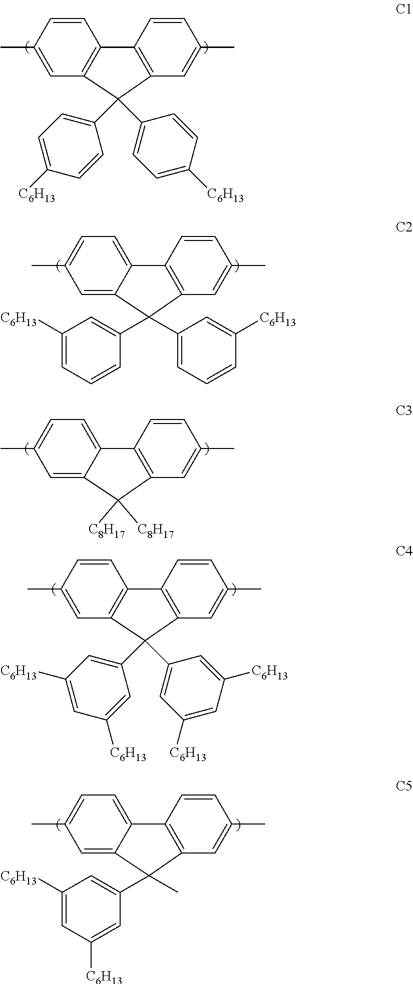

Particularly preferably the organic charge transporting polymer layer present in the electrode of the invention comprises the repeat units (Ai) and/or (Aii), (Bi) and/or (Bii) and (C). More preferably the organic charge transporting polymer layer present in the electrode of the invention comprises the repeat units (Ai) or (Aii) and (Bi) and/or (Bii) and (C).

The amount of each of the different repeat units present in the organic charge transporting polymer layer may vary. Preferably, however, the total wt % of repeat units of formula (A) and (C) is 70 to 98% wt and more preferably 80 to 95% wt. Preferably the total wt % of repeat units of formula (A) is 25 to 95% wt and more preferably 30 to 90% wt. Preferably the total wt % of repeat units of formula (C) is 10 to 70 wt % and more preferably 15 to 65 wt %. Preferably the total wt % of repeat units of formula (B) is 5 to 20% wt and more preferably 7.5 to 12.5 wt %.

Particularly preferably the organic charge transporting polymer layer comprises the repeat units:

(i) A1, B2, B3 and C4;

(ii) A1, B2, B3, C3 and C4;

(iii) A1, B2 and B3;

(iv) A4, B1 and C3; or

(v) A3, B2, C3, and C4.

Still more preferably the organic charge transporting polymer layer comprises the repeat units:
75% wt (A1), 5% wt (B2), 5% wt (B3) and 15% wt (C4)
30% wt (A1), 7.5% wt (B2), 7.5% (B3), 5% wt (C3) and 50% (C4)
90% wt (A1), 5% wt (B2) and 5% wt (B3)
42.5% wt (A4), 7.5% wt (B1) and 50% wt (C3).
30% wt (A3), 7.5% wt (B2), 12.5 5 wt (C3) and 50% (C4)
30% wt (A1), 5% wt (B2), 5 wt % (B3), 10% wt (C3) and 50% (C4)

Preferred organic charge transporting polymer layers further comprise a dopant. Preferred dopant is a partially fluorinated fullerene. The fullerene of the partially fluorinated fullerene may be any carbon allotrope in the form of a hollow sphere or ellipsoid. The fullerene preferably consists of carbon atoms arranged in 5, 6 and/or 7 membered rings, preferably 5 and/or 6 membered rings. C₆₀ Buckminster Fullerene is particularly preferred.

The partially fluorinated fullerene preferably has formula CₐF_{b} wherein b is in the range of 10-60, optionally 10-50, and a is more than b, e.g. a is 40 to 90, more preferably 50 to 70. Examples include C₆₀F₁₈, C₆₀F₂₀, C₆₀F₃₆, C₆₀F₄₈, C₇₀F₄₄, C₇₀F₄₆, C₇₀F₄₈, and C₇₀F₅₄. C₆₀F₃₆ is particularly preferred. Partially fluorinated fullerenes and their synthesis are described in more detail in, for example, Andreas Hirsch and Michael Brettreich, “Fullerenes: Chemistry and Reactions”, 2005 Wiley-VCH Verlag GmbH & Co KGaA, “The Chemistry Of Fullerenes”, Roger Taylor (editor) Advanced Series in Fullerenes—Vol. 4 and “Chemical Communications, 1996(4), 529-530. The partially fluorinated fullerene may consist of carbon and fluorine only or may include other elements, for example halogens other than fluorine and/or oxygen.

When present, the amount of dopant present in the organic charge transporting polymer layer is preferably 0.1 to 40 wt %, more preferably 1 to 25 wt % and still more preferably 5 to 20 wt %.

As discussed above, the organic charge transporting polymer layer is preferably deposited from solution and particularly preferably from a solution comprising an aromatic solvent.

In preferred electrodes of the present invention the organic charge transporting polymer layer has a thickness of 1 nm to 100 nm, more preferably 5 nm to 40 nm and still more preferably 15 nm to 30 nm when measured from the top of the layer to the surface of the substrate.

The electrode of the present invention is preferably incorporated into a layered structure wherein at least one polymeric layer is deposited on the electrode. Preferably the polymeric layer comprises acidic groups. Preferably the polymeric layer is a hole injection layer. Representative examples of hole injection layers include poly(3,4-ethylenedioxythiophene) (PEDOT), PEDOT:PSS, polythiophene conductive polymer, polyaniline (PANI), polypyrole, polyacrylic acid or a fluorinated sulfonic acid, for example Nafion. Preferably the polymeric layer is solution processed. Advantageously the organic charge transporting polymer layer constitutes a hydrophilic layer on the metal grid and facilitates deposition of polymeric layers by solution processing from water. Preferably the polymeric layer, e.g. HIL, is deposited from solution, e.g. water.

The electrode or the layered structure of the present invention is preferably used in the manufacture of organic electronic devices. Organic electronic devices comprising an electrode or a layered structure of the present invention therefore form a further aspect of the present invention. Examples of organic electronic devices that may be prepared using the electrode and the layered structure of the present invention include organic light emitting diodes (OLEDs), organic photovoltaic devices (OPVs), organic photosensors, organic transistors and organic memory array devices. Some of these devices comprise an anode, a hole injection layer, an active organic layer and a cathode. The hole injection layer is preferably in between the anode and the active organic layer. The active organic layer is preferably in between the hole injection layer and the cathode. The electrode of the present invention is preferably present as an anode or cathode and more preferably as an anode. The anode is preferably prepared by the method described below. The hole injection layer and the active layer are preferably deposited by solution processing, e.g. spin coating or ink jet printing. The cathode is preferably deposited by thermal evaporation.

The electrode and the layered structure of the present invention are particularly beneficial in the manufacture of OLEDs. In OLEDs the active organic layer is an organic light-emitting layer. In OLEDs the electrode of the present invention is preferably an anode.

Preferably the device, e.g. OLED, comprises:

(i) an anode;
(ii) a hole injection layer;
(iii) at least one light emitting layer; and
(iv) a cathode,
wherein the anode comprises an electrode as hereinbefore defined.

Preferred devices further comprise a substrate. Still more preferably the device, e.g. OLED, comprises:

(i) a substrate;
(ii) an anode on the substrate;
(iii) a hole injection layer on said anode;
(iv) at least one light emitting layer on said hole injection layer; and
(v) a cathode on said light emitting layer,
wherein the anode comprises an electrode as hereinbefore defined

In preferred devices of the present invention, the hole injection layer comprises acidic groups. In particularly preferred devices the hole injection layer comprises PEDOT or PEDOT:PSS. Other high conductivity hole injection layers are also commercially available.

Particularly preferred devices, e.g. OLEDs, additionally comprise an interlayer. Preferably the interlayer is in between the hole injection layer and the light emitting layer.

Preferred devices, e.g. OLEDs, of the invention comprise:

(i) a substrate;
(ii) an anode as hereinbefore defined;
(iii) a hole injection layer;
(iv) an interlayer;
(v) at least one light emitting layer; and
(vii a cathode.

Further preferred devices, e.g. OLEDs, additionally comprise an electron injection layer. Preferably the electron injection layer is in between the light emitting layer and the cathode. Conventional electron injection layers may be used. Further preferred devices, e.g. OLEDs, additionally comprise an electron transport layer. Preferably the electron transport layer is in between the light emitting layer and the cathode or when an electron injection layer is present in between the light emitting layer and the electron injection layer.

Preferred devices of the invention are also encapsulated to avoid ingress of moisture and oxygen. Conventional encapsulation techniques may be used. An advantage of the devices of the present invention, however, is that they are more resistant to degradation and therefore have longer lifetimes than conventional devices.

The substrate may be any material conventionally used in the art such as glass or plastic. Optionally the substrate is pre-treated to improve adhesion thereto. Preferably the substrate is transparent. Preferably the substrate also has good barrier properties to prevent ingress of moisture or oxygen into the device.

The anode preferably comprises an electrode as hereinbefore defined. In some embodiments the anode further comprises indium tin oxide (ITO) or indium zinc oxide (IZO). In such devices the electrode of the invention is preferably deposited on the ITO or IZO in the form of a grid. In other embodiments the anode does not comprise ITO or IZO. Particularly preferred devices of the present invention do not comprise ITO or IZO. Preferably the anode is transparent.

When present the ITO or IZO present in the anode is preferably deposited on the substrate by thermal evaporation. The electrode, e.g. anode, of the present invention is then preferably formed on top of the ITO or IZO by the method described below. When ITO and IZO are absent, the electrode, e.g. anode, is preferably formed on the substrate by the method described below. The anode is preferably 20 to 200 nm thick and more preferably 10 to 100 nm thick.

The hole injection layer preferably comprises a conducting material. It assists hole injection from the anode into the light emitting layer. Representative examples of materials that may be used to form the hole injection layer include PANI (polyaniline), polypyrole, polythiophene conductive polymer, unsubstituted or substituted, doped poly(ethylene dioxythiophene) (PEDOT), in particular PEDOT doped with a charge-balancing polyacid such as polystyrene sulfonate (PSS) as disclosed in EP0901176 and EP0947123 (PEDOT:PSS), polyacrylic acid or a fluorinated sulfonic acid, for example Nafion®; polyaniline as disclosed in U.S. Pat. No. 5,723,873 and U.S. Pat. No. 5,798,170; and unsubstituted or substituted polythiophene or poly(thienothiophene). Other suitable materials are summarized in the book by Zigang Li and Hong Meng, Chapter 3.3 page 303-12. Examples of conductive inorganic materials include transition metal oxides such as VOₓ, MOₓ and RuOₓ as disclosed in Journal of Physics D: Applied Physics (1996), 29(11), 2750-2753. Preferably the hole injection layer comprises PEDOT, PSS, PEDOT:PSS or polythiophene conductive polymer, especially PEDOT:PSS. Suitable materials for use as the hole injection layer are commercially available.

Preferably the hole injection layer is deposited by a solution-based processing method. Preferably water is used as the solvent. Any conventional solution-based processing method may be used. Representative examples of solution-based processing methods include spin coating, gravure printing, flexographic printing, roll to roll printing, dip coating, slot die coating, doctor blade coating and ink-jet printing. In preferred methods, however, depositing is by spin coating. The parameters used for spin coating the hole injection layer such as spin coating speed, acceleration and time are selected on the basis of the target thickness for the layer. After deposition, the hole injection layer is preferably annealed by heating, e.g. at 110 to 200° C. for 5 to 30 minutes in air.

The thickness of the hole injection layer is preferably 15 to 200 nm and more preferably 30 to 50 nm.

One preferred interlayer comprises a repeat unit which is an o-phenylene, m-phenylene or p-phenylene group, particularly a p-phenylene group. Preferably the phenylene repeat unit is substituted. Particularly preferably the phenylene repeat unit is of formula (D):

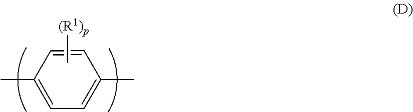

wherein
R¹ represents C₁₋₁₆ alkyl, C₁₋₁₆ alkoxy, C₁₋₁₆ alkylthio, C₅₋₁₄ aryl, C₅₋₁₄ aryloxy, C₅₋₁₅ arylthio, arylalkyl, arylalkoxy, arylalkylthio or a monovalent heterocyclic group; and
p is 0 or an integer.

In preferred repeat units of formula (D), p is 1 or 2, especially 2. When p is 2, the groups R¹ are preferably present at positions 2 and 5 or 3 and 6 of the ring. When p is greater than 1, the R¹ groups present may be the same or different.

In further preferred repeat units of formula (D), R¹ represents C₁₋₁₆ alkyl, more preferably C₁₋₁₀ alkyl and still more preferably C₁₋₆ alkyl, e.g. methyl or hexyl.

Two particularly preferred repeat units of formula (D) are shown below.

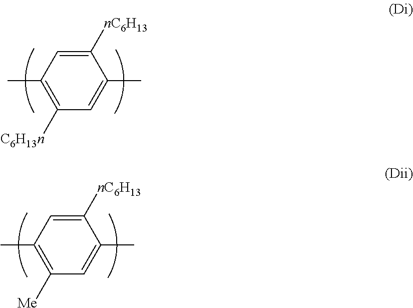

Repeat units of formula (Di) are particularly preferred. Repeat units of formula (D) may be incorporated into interlayer polymers using monomers as described in EP2123691.

Further preferred interlayers comprise a repeat unit of formula (Ai) as described above in relation to the charge transporting polymer layer. A particularly preferred repeat unit of formula (Ai) is (A1). Repeat units of formula (Ai) may be incorporated into interlayer polymers using monomers as described in WO2005/049546.

Further preferred interlayer polymers comprise a repeat unit of formula (Bi) as described above in relation to the charge transporting polymer layer. A particularly preferred repeat unit of formula (Bi) is (B1). Repeat units of formula (Bi) may be incorporated into interlayer polymers using monomers as described in WO2005/052027.

One preferred interlayer of the devices of the present invention comprise repeat units of formulae (D), (Ai) and (Bi). Particularly preferred interlayer polymers comprise repeat units of formulae (Di), (A1) and (B1). Especially preferred interlayer polymers comprise 40-60% wt (Di), 30-50% (A1) and 2.5-10% wt (B1).

Preferably the interlayer is deposited by a solution-based processing method. Any conventional solution-based processing method may be used. Representative examples of solution-based processing methods include spin coating, gravure printing, flexigraphic printing, roll to roll printing, dip coating, slot die coating, doctor blade coating and ink-jet printing. In preferred methods, however, depositing is by spin coating or ink jet printing. The parameters used for spin coating the interlayer such as spin coating speed, acceleration and time are selected on the basis of the target thickness for the layer. After deposition, the interlayer is preferably crosslinked by heating, e.g. at 150 to 200° C. for 30 to 120 minutes in a glove box.

The thickness of the interlayer is preferably 5 to 50 nm and more preferably 10 to 40 nm.

The light emitting layer present in the devices of the present invention may comprise any conventional light emitting compound and/or light emitting polymer. The light emitting layer present in the devices of the present invention may comprise a green light emitter, a red light emitter, a blue light emitter or any combination thereof. In some preferred devices a single light emitter is present. In other preferred devices of the invention the light emitting layer comprises each of a green light emitter, a red light emitter and a blue light emitter. This results in white light.

Preferred light emitting polymers present in the devices of the present invention comprise a repeat unit of formula (D) as described above in relation to the interlayer. More preferably the light emitting polymer comprises a repeat unit of formula (Di) or (Dii) and still more preferably a repeat unit of formula (Di).

Preferred light emitting polymers further comprise a repeat unit of formula (C) as described above in relation to the charge transporting polymer layer. More preferably the light emitting polymer comprises a repeat unit of formula (C1), (C2), (C3) or (C5).

Preferred light emitting polymers further comprise a repeat unit of formula (Bii) as described above in relation to the charge transporting polymer layer. More preferably the light emitting polymer comprises a repeat unit of formula (B2) or (B3).

Preferred light emitting polymers further comprise a repeat unit of formula (E):

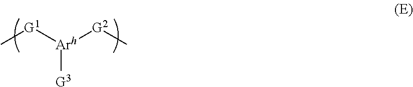

wherein Ar^{h} comprises a substituted or unsubstituted heteroaryl group comprising 5 or 6 ring atoms; and
each G is the same or different and independently comprises a substituted or unsubstituted C₅₋₁₄ aryl or C₅₋₁₄ heteroaryl group.

Representative examples of substituents that may be present on the aryl or heteroaryl groups are halide, cyano, C₁₋₁₆ alkyl, C₁₋₁₆ fluoroalkyl, C₁₋₁₆ alkoxy, C₁₋₁₆ fluoroalkoxy, C₅₋₁₄ aryl and C₅₋₁₄ heteroaryl.

In preferred repeat units of formula (E) Ar^{h} is a 6 membered ring. The ring preferably comprises 1, 2 or 3 heteroatoms. Particularly preferably the ring comprises 2 or 3 and especially 3 heteroatoms. Nitrogen is the preferred heteroatom. Especially preferably Ar^{h} is a 1,3,5-triazine ring.

In further preferred repeat units of formula (E) G¹ is an aryl group. Particularly preferably G¹ is a C₆ aryl group, e.g. phenyl. In further preferred repeat units of formula (E) G² is an aryl group. Particularly preferably G² is a C₆ aryl group, e.g. phenyl. Still more preferably G¹ and G² are the same.

A particularly preferred repeat unit of formula (E) is (Ei) as shown below:

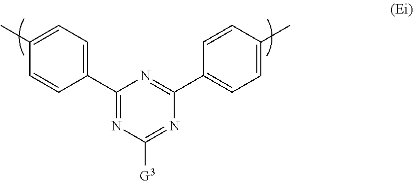

wherein G³ is as defined above in relation to formula (E).

Preferably G³ is also a substituted or unsubstituted phenyl group. Preferably G³ is substituted. Thus a further preferred repeat unit of formula (E) is formula (Eii) shown below:

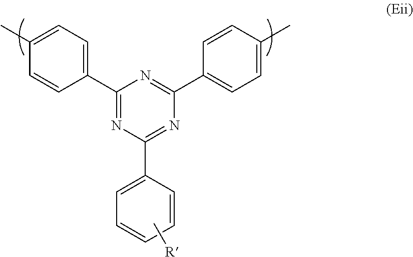

wherein R′ is H or unsubstituted or substituted branched or linear C₁₋₁₆ alkyl or C₁₋₁₆ alkoxy, preferably alkyl. Particularly preferably R′ is linear C₁₂ alkyl. Preferably R′ is in the para position.

A particularly preferred repeat unit (Eiii) is shown below:

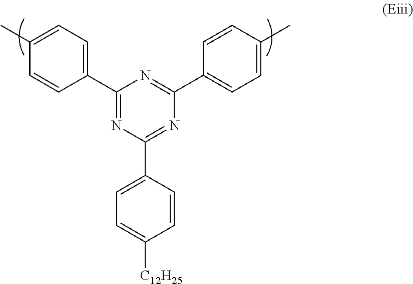

Repeat units of formula (E) may be incorporated into light emitting polymers using monomers as described in WO2002/083760.

Further preferred light emitting polymers comprise a light emitting unit. Preferred light emitting units are present as end caps in the polymer. Preferred light emitting units are of formula (F):

ML¹_{q}L²ᵣL³ₛ (F)

wherein M is a metal; each of L¹, L² and L³ is a ligand; q is an integer; r and s are each independently 0 or an integer; and the sum of (a·q)+(b·r)+(c·s) is equal to the number of coordination sites available on M, wherein a is the number of ligating sites on L¹, b is the number of ligating sites on L² and c is the number of ligating sites on L³.

In preferred units of formula (F) L¹, L² and L³ are bidentate ligands. In further preferred units of formula (F) L¹, L² and L³ are biaryl bidentate ligands, especially preferably biaryl bidentate ligands comprising one or more (e.g. one) heteroatoms. Preferably the heteroatom or heteroatoms are oxygen or nitrogen. In particularly preferred units of formula (F) L¹, L² and L³ are biaryl bidentate nitrogen-containing ligands. The preferred metal M is iridium.

Particularly preferred light emitting units of formula (F) are those in which at least one of L¹, L² and L³ are of the following structure shown below as formula (Fi):

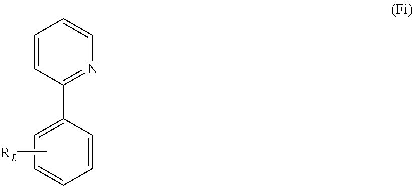

wherein R_{L} is H or Ar⁶ wherein Ar⁶ is aryl, especially substituted C₆ aryl.

Preferred light emitting units of formula (F) are shown below as formula (Fii):

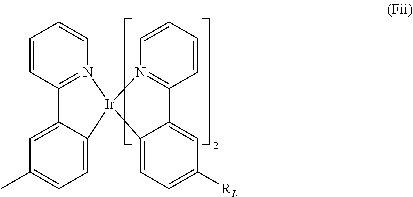

wherein R_{L} is as defined above.

A particularly preferred light emitting unit of formula (F) is shown below as formula (Fiii):

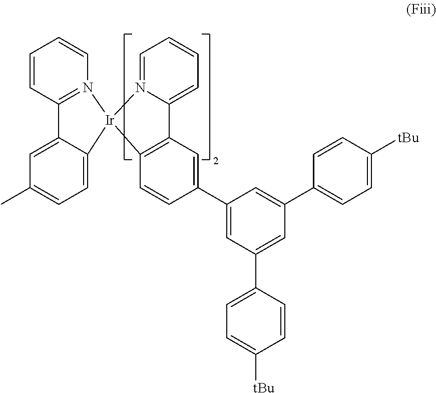

Light emitting units of formula (F) may be incorporated into light emitting polymers by the methods described in US2008/100199 and WO2013/021180.

Further preferred light emitting polymers present in the devices of the present invention comprise a repeat unit of formula (H):

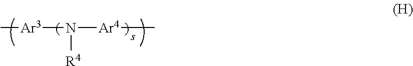

wherein Ar³ and Ar⁴ are unsubstituted or substituted C₅₋₁₄ aryl or C₅₋₁₄ heteroaryl groups, s is greater than or equal to 1, preferably 1 or 2, and R⁴ is H or a substituent selected from C₁₋₁₆ alkyl, C₅₋₁₄ aryl or C₅₋₁₄ heteroaryl, most preferably aryl or heteroaryl. Any of the aryl or heteroaryl groups in the unit of formula (H) may be substituted. Preferred substituents include C₁₋₁₆ alkyl and C₁₋₁₆ alkoxy groups. Any of the aryl or heteroaryl groups in the repeat unit of formula (H) may be linked by a direct bond or a divalent linking atom or group. Preferred divalent linking atoms and groups include O, S, substituted N and substituted C.

Particularly preferred repeat units of formula (H) are those of formula (Hi-iii) shown below. Those of formula (Hiii) are particularly preferred.

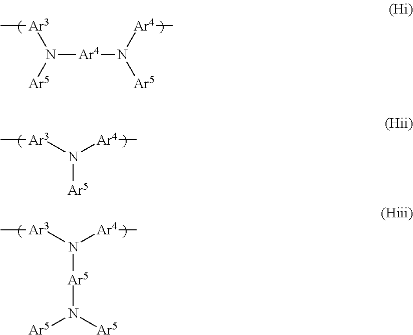

wherein Ar³ and Ar⁴ are as defined above; and Ar⁵ is unsubstituted or substituted C₅₋₁₄ aryl or C₅₋₁₄ heteroaryl. When present, preferred substituents for Ar⁵ include C₁₋₁₆ alkyl and C₁₋₁₆ alkoxy groups.

In preferred repeat units of formula (H) each of Ar³, Ar⁴ and Ar⁵ are aryl, especially preferably C₆ aryl. Preferably Ar³ and Ar⁴ are unsubstituted. Ar⁵ is preferably substituted. Preferred substituents are C₁₋₁₆ alkyl, more preferably C₁₋₆ alkyl.

A particularly preferred repeat unit of formula (H) is (Hiv) shown below:

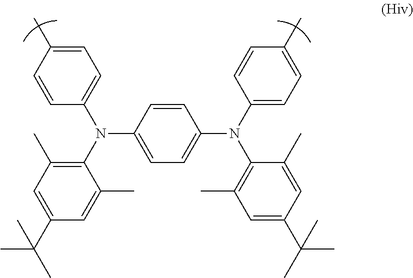

Repeat units of formula (H) may be incorporated into light emitting polymers using monomers as described in WO2008/016090, WO2008/111658, WO2009/110642 and WO2010/013724.

Further preferred light emitting polymers present in the devices of the present invention comprise repeat units of formula (I):

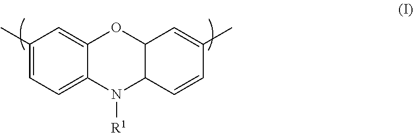

wherein R¹ is selected from unsubstituted or substituted C₁₋₁₆ alkyl, wherein one or more non-adjacent C atoms may be replaced with O, S, N, CO and —COO—, unsubstituted or substituted C₁₋₁₆ alkenyl, unsubstituted or substituted C₁₋₁₆ alkoxy, unsubstituted or substituted C₅₋₁₄ aryl, unsubstituted or substituted arylalkyl, unsubstituted or substituted C₅₋₁₄ heteroaryl and unsubstituted or substituted heteroarylalkyl. Optional substituents are preferably selected from the group consisting of C₁₋₁₆ alkyl or C₁₋₁₆ cycloalkyl wherein one or more non-adjacent C atoms may be replaced with O, S, N, C═O and —COO—, unsubstituted or substituted C₅₋₁₄ aryl, unsubstituted or substituted C₅₋₁₄ heteroaryl, C₁₋₁₆ alkoxy, C₁₋₁₆ alkylthio, fluorine, cyano and arylalkyl.

In preferred repeat units of formula (I) R¹ is an unsubstituted or substituted C₅₋₁₄ aryl, e.g. a C₆ aryl. Preferred substituents of aryl groups are C₁₋₁₆ alkyl and still more preferably an unsubstituted C₁₋₁₆ alkyl group such as an unsubstituted C₁₋₆ alkyl group.

A particularly preferred repeat unit of formula (I) is shown below as formula (Ii):

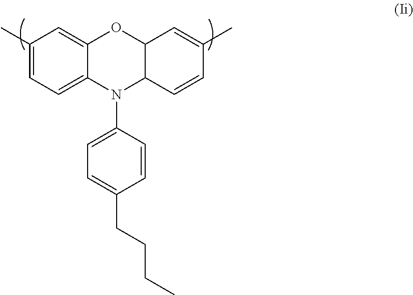

Repeat units of formula (I) may be incorporated into light emitting polymers using monomers described WO2004/060970.

Further preferred light emitting polymers present in the devices of the present invention comprise repeat units of formula (J):

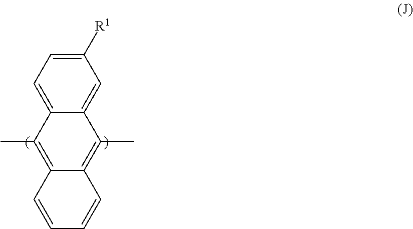

wherein R¹ is selected from unsubstituted or substituted C₁₋₁₆ alkyl, wherein one or more non-adjacent C atoms may be replaced with O, S, N, CO and —COO—, unsubstituted or substituted C₁₋₁₆ alkenyl, unsubstituted or substituted C₁₋₁₆ alkoxy, unsubstituted or substituted C₅₋₁₄ aryl, unsubstituted or substituted arylalkyl, unsubstituted or substituted C₅₋₁₄ heteroaryl and unsubstituted or substituted heteroarylalkyl. Optional substituents are preferably selected from the group consisting of C₁₋₁₆ alkyl or C₁₋₁₆ cycloalkyl wherein one or more non-adjacent C atoms may be replaced with O, S, N, C═O and —COO—, unsubstituted or substituted C₅₋₁₄ aryl, unsubstituted or substituted C₅₋₁₄ heteroaryl, C₁₋₁₆ alkoxy, C₁₋₁₆ alkylthio, fluorine, cyano and arylalkyl.

In preferred repeat units of formula (J) R¹ is an unsubstituted or substituted C₁₋₁₆ alkyl. Preferred substituents are C₁₋₁₆ alkyl, still more preferably an unsubstituted C₁₋₁₆ alkyl group and yet more preferably unsubstituted C₁₋₈ alkyl.

A particularly preferred repeat unit of formula (J) is shown below as formula (Ji):

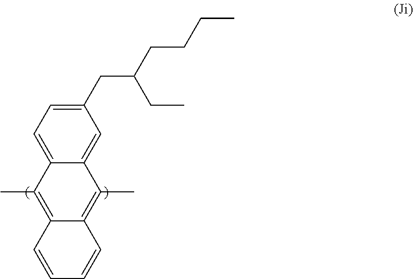

Repeat units of formula (J) may be incorporated into light emitting polymers using monomers described in WO2012/086670 and WO2012/086671.

One preferred green light emitting layer of the devices of the present invention comprises a polymer having repeat units of formulae (D), (C), (E), (F) and (B). A more preferred green light emitting polymer comprises repeat units of formulae (Di), (C1), (Eiii), (Fiii), (B2) and (B3), e.g. in the ratio 50% wt (Di), 20.7% wt (C1), 11.5% wt (Eiii), 7.8% wt (Fiii), 5% wt (B2) and 5% wt (B3).

One preferred red light emitting layer of the devices of the present invention comprises at least one polymer and a red emitting compound. Suitable red emitting compounds are disclosed in WO2009/157424, WO2010/084977, GB2435194 and EP1449238, the contents of which are incorporated herein by reference. In preferred emitters, the metal is iridium. More preferably the red emitting compound is an iridium complex.

Preferably the red light emitting compound is a compound of formula (G):

ML¹_{q}L²ᵣL³ₛ (G)

wherein

M is a metal;

each of L¹, L² and L³ is a ligand;

q is an integer;

r and s are each independently 0 or an integer; and

the sum of (a·q)+(b·r)+(c·s) is equal to the number of coordination sites available on M, wherein a is the number of ligating sites on L¹, b is the number of ligating sites on L² and c is the number of ligating sites on L³.

Suitable metals M include: lanthanide metals (e.g. cerium, samarium, europium, terbium, dysprosium, thulium, erbium and neodymium) and d-block metals. Preferred d-block metals are those in rows 2 and 3 i.e. elements 39 to 48 and 72 to 80, in particular ruthenium, rhodium, palladium, rhenium, osmium, iridium, platinum and gold. More preferably M is a d-block metal and still more preferably M is iridium.

Suitable ligands for the lanthanide metals include oxygen or nitrogen donor systems such as carboxylic acids, 1,3-diketonates, hydroxy carboxylic acids, Schiff bases including acyl phenols and iminoacyl groups. Ligands comprising a bidentate group as illustrated below are preferred:

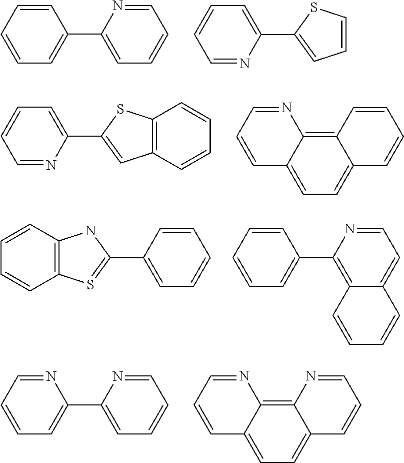

A particularly preferred bidentate ligand is:

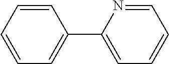 [SMILES: c1ccc(-c2ccccn2)cc1]

A particularly preferred red light emitting compound is shown below as formula (Gi):

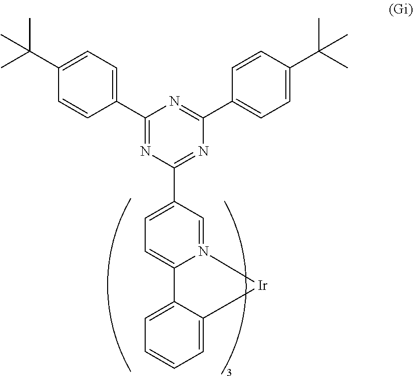

More preferably the red emitting layer comprises a blend of two polymers and a red emitting compound. Preferably the polymer(s) form a triplet diffusion prevention layer. Preferably the red light emitting layer comprises a first polymer having repeat units of formulae (D), (A), (C) and (B) and still more preferably (Di), (A1), (C2) and (B2). Preferably the first polymer is blended with a red light emitting compound of formula (Gi), e.g. so that the resulting blend comprises 50% wt (Di), 36.5% wt (A1), 3.2% wt (C2), 10% wt (B2) and 0.6% wt (Gi). Preferably the red light emitting layer comprises a second polymer having repeat units of formulae (D), (E), (C) and (B) and still more preferably (Di), (Eiii), (C2) and (B2). Preferably the second polymer is blended with a red light emitting compound of formula (Gi), e.g. so that the resulting blend comprises 50% wt (Di), 22% wt (Eiii), 17.7% wt (C2), 10% wt (B2) and 0.6% wt (Gi). Preferably the first polymer/red light emitting compound blend and the second polymer/red light emitting compound blend are blended in a weight ratio of about 40:60 to 60:40, e.g. about 50:50.

One preferred blue light emitting layer comprises a blend of two polymers and more preferably a blend of a blue light emitting polymer and a triplet control polymer. Preferably the blue light emitting layer comprises a blue light emitting polymer having repeat units of formulae (C), (A) and (I) and still more preferably (C1), (C3), (C2), (A2) and (Ii). Preferably the repeat units are present in the ratio 36% wt (C1), 45% wt (C2), 14% wt (C3), 4% wt (A2) and 1% wt (Ii). Preferably the blue light emitting layer comprises a triplet control polymer having repeat units of formulae (C) and (J) and still more preferably (C5) and (Ji). Preferably the repeat units are present in the ratio 50% wt (C5) and 50% wt (Ji) Preferably the blue light emitting polymer and the triplet control polymer are blended in a weight ratio of about 95:5 to 99.5:0.5, e.g. about 99:1.

Preferably the light emitting layers are present in the order green, red and blue wherein the green layer is closest to the anode.

One preferred green light emitting layer of the devices of the present invention comprises a polymer having repeat units of formulae (D), (E) and (C) and a light emitting compound. The ratio of polymer to compound is preferably 50:50 to 80 to 20 by weight and more preferably 60:40 to 75:25 by weight. A more preferred green light emitting polymer comprises repeat units of formulae (Di), (Eiii) and (C1), e.g. in the ratio 50% wt (Di), 10% wt (Eiii) and 40% wt (C1). Preferably the light emitting compound is a compound of formula (K) as shown below:

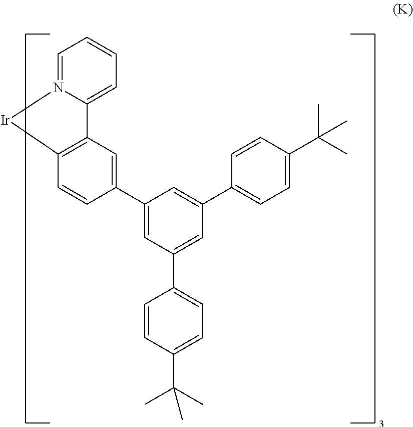

Suitable light emitting polymers may be synthesised according to the methods disclosed in the art, e.g. in by Suzuki polymerisation as described in WO00/53656.

Preferably the light emitting layer is deposited by a solution-based processing method. Any conventional solution-based processing method may be used. Representative examples of solution-based processing methods include spin coating, gravure printing, flexigraphic printing, roll to roll printing, dip coating, slot die coating, doctor blade coating and ink-jet printing. In preferred methods, however, depositing is by spin coating or ink jet printing. The parameters used for spin coating the light emitting layer such as spin coating speed, acceleration and time are selected on the basis of the target thickness for the layer. When the light emitting layer is comprised of, for example, green, red and blue light emitting layers, the layers are preferably deposited step-wise by the above-described techniques. After depositing, the light emitting layer is preferably dried, e.g. at 100-200° C. in a glove box.

The total thickness of the light emitting layer is preferably 50 to 350 nm and more preferably 75 to 150 nm. The thickness of the green light emitting layer is preferably 20 to 30 nm. The thickness of the red light emitting layer is preferably 10 to 25 nm. The thickness of the blue light emitting layer is preferably 50 to 80 nm.

The cathode may comprise any material having a workfunction allowing injection of electrons into the active, e.g. light-emitting, layer. Work functions of metals can be found in, for example, Michaelson, J. Appl. Phys. 48(11), 4729, 1977. The cathode may consist of a single material such as a layer of aluminium. Alternatively, it may comprise a plurality of metals, for example a bilayer or trilayer of metals. A particularly preferred cathode comprises a layer of NaF, a layer of Al and a layer of Ag.

The cathode may be opaque or transparent. Transparent cathodes are particularly advantageous for active matrix devices because emission through a transparent anode in such devices is at least partially blocked by drive circuitry located underneath the emissive pixels. A transparent cathode comprises a layer of an electron injecting material that is sufficiently thin to be transparent. Typically, the lateral conductivity of this layer will be low as a result of its thinness. In this case, the layer of electron injecting material is used in combination with a thicker layer of transparent conducting material such as indium tin oxide.

Preferably the cathode is deposited by thermal evaporation. The cathode is preferably 100 to 400 nm thick and more preferably 200 to 350 nm thick.

Suitable encapsulants include a sheet of glass, films having suitable barrier properties such as silicon dioxide, silicon monoxide, silicon nitride or alternating stacks of polymer and dielectric as disclosed in, for example, WO 01/81649 or an airtight container as disclosed in, for example, WO 01/19142. In the case of a transparent cathode device, a transparent encapsulating layer such as silicon monoxide or silicon dioxide may be deposited to micron levels of thickness, although in one preferred embodiment the thickness of such a layer is in the range of 20-300 nm. A material for absorption of any atmospheric moisture and/or oxygen that may permeate through the substrate or encapsulant may optionally be disposed between the substrate and the encapsulant.

Preferred devices of the present invention have one or more of the following structural characteristics:
Substrate: Glass surface
Anode: Cu grid
Anode thickness: 10 to 100 nm
Charge transporting polymer (CTP) layer: Polymer comprising repeat units (Ai) or (Aii) and (Bi) and/or (Bii) and (C).
CTP layer thickness: 10 to 40 nm
Hole injection layer: Conductive PEDOT:PSS
Hole injection layer thickness: 100 to 300 nm
Light emitting layer: Green light emitting layer or multi layered stack comprising green light emitting layer/red light emitting layer/blue light emitting layer
Light emitting layer thickness: 50 to 150 nm
Cathode: NaF/Al/Ag
Cathode thickness: 200 to 350 nm

Particularly preferred devices of the present invention are lighting tiles. Preferred lighting tiles have a surface area of 0.1 to 1000 cm², more preferably 0.2 to 750 cm², still more preferably 1 to 500 cm² and yet more preferably 10 to 250 cm².

Preferred methods for making an electrode of the present invention comprise depositing a metal grid on a substrate by photolithography or by electroless plating. The metal may be deposited in the form of a grid or may be patterned after deposition. Preferably the metal is deposited in the form of a grid. Photolithography may be carried out by techniques conventional in the art. Electroless plating may also be carried out by techniques conventional in the art. Preferably electroless plating is carried out by the method described in WO2004/068389 to Conductive Inkjet Technology Limited, the entire contents of which are hereby incorporated by reference. This method is advantageous because it enables deposition of the metal in the form of a grid by ink jet printing.

In preferred methods of the invention the metal grid is treated with UV/ozone prior to deposition of the organic charge transporting polymer layer. The treatment with UV/ozone is preferably for less than 10 seconds.

In preferred methods of the invention the metal grid is treated with acid prior to depositing the organic charge transporting polymer layer. Preferably the acid treatment follows UV/ozone treatment. Any acid may be used, e.g. inorganic acids or organic acids. The purpose of the acid is to remove copper oxide formed on the surface of the copper. Preferably the acid is acetic acid. The acid treatment may be carried out in any conditions that will remove copper oxide from the surface of the copper. Preferably, however, the acetic acid is heated, e.g. to 50 to 100° C. and more preferably 55 to 75° C. Preferably treatment is carried out 30 seconds to 5 minutes and more preferably about 1 minute.

In preferred methods of the invention the depositing of the charge transporting layer is by solution processing. Representative examples of solution-based processing methods include spin coating, gravure printing, flexigraphic printing, roll to roll printing, dip coating, slot die coating, doctor blade coating and ink-jet printing. In preferred methods, however, depositing is by spin coating or ink jet printing. The parameters used for spin coating the polymer layer such as spin coating speed, acceleration and time are selected on the basis of the target thickness for the layer. The solvent used for deposition is as discussed above.

In preferred methods of the invention the electrode is treated with UV/ozone prior to deposition of the polymeric layer. The treatment with UV/ozone is preferably for less than 10 seconds. This improves the adhesion of the polymeric layer.

In preferred methods of the invention the depositing of the polymeric layer, e.g. hole injection layer, is by solution processing. Representative examples of solution-based processing methods include spin coating, gravure printing, flexigraphic printing, roll to roll printing, dip coating, slot die coating, doctor blade coating and ink-jet printing. In preferred methods, however, depositing is by spin coating or ink jet printing. The parameters used for spin coating the polymer layer such as spin coating speed, acceleration and time are selected on the basis of the target thickness for the layer.

Particularly preferred methods of making a device of the present invention comprise:
(i) depositing a metal grid on a substrate;
(ii) treating said metal grid with UV/ozone;
(iii) treating said metal grid with acid;
(iv) depositing an organic charge transporting polymer layer on at least one surface of said metal grid;
(v) treating said organic charge transporting polymer with UV/ozone;
(vi) depositing a hole injection layer on said organic charge transporting polymer layer;
(vii) optionally depositing an interlayer on said hole injection layer;
(viii) depositing at least one light emitting layer on said hole injection layer or where present said interlayer; and
(ix) depositing a cathode on said electrode injection layer.

Preferably the metal grid is deposited by photolithography or electroless plating, and more preferably electroless plating, in step (i). Preferably the charge transporting polymer is deposited by solution processing, e.g. spin coating, in step (iv). Preferably each of steps (vi)-(viii) are carried out by solution processing. Preferably step (ix) is carried out by thermal vapour deposition.

### BRIEF DESCRIPTION OF THE DRAWINGS

FIG. 1a is a schematic of a typical OLED;

FIG. 1b is a schematic of a typical OLED;

FIG. 2a is a schematic of a Cu grid deposited on a substrate;

FIG. 2b is a schematic of an OLED prepared according to the examples of the present invention;

FIG. 3 is a flow diagram of the method used to prepare the OLED in the example of the present invention;

FIG. 4a shows a plot of efficiency, measured as Cd/A, versus voltage (V) for devices having unprotected copper or gold anodes;

FIG. 4b shows a plot of external quantum efficiency versus voltage (V) for devices having unprotected copper or gold anodes;

FIG. 4c shows a plot of efficiency, measured as Lm/W, versus voltage (V) for devices having unprotected copper or gold anodes;

FIG. 4d shows a plot of efficiency, measured as Lm/W, versus luminance (cd/m²) for devices having unprotected copper or gold anodes;

FIG. 5a shows a plot of efficiency, measured as Cd/A, versus voltage (V) for devices having unprotected copper or gold anodes;

FIG. 5b shows a plot of efficiency, measured as Lm/W, versus voltage (V) for devices having unprotected copper or gold anodes;

FIG. 5c shows a plot of luminance (cd/m²) versus time (hours) for devices having unprotected copper or gold anodes

FIG. 6a shows a plot of current density (mA/cm²) versus voltage (V) for devices having either a copper anode rinsed with acetic acid prior to deposition of the HIL or a gold anode;

FIG. 6b shows a plot of efficiency, measured as Lm/W, versus voltage (V) for devices having either a copper anode rinsed with acetic acid prior to deposition of the HIL or a gold anode;

FIG. 6c shows a plot of efficiency, measured as Cd/A, versus voltage (V) for devices having either a copper anode rinsed with acetic acid prior to deposition of the HIL or a gold anode;

FIG. 7a shows a plot of current density (mA/cm²) versus voltage (V) for devices of the invention comprising a protective charge transporting polymer layer and comparative devices comprising a gold anode;

FIG. 7b shows a plot of efficiency, measured as Lm/W, versus voltage (V) for devices of the invention comprising a protective charge transporting polymer layer and comparative devices comprising a gold anode;

FIG. 7c shows a plot of efficiency, measured as Cd/A, versus voltage (V) for devices of the invention comprising a protective charge transporting polymer layer and comparative devices comprising a gold anode;

FIG. 7d shows a plot of EQE versus voltage (V) for devices of the invention comprising a protective charge transporting polymer layer and comparative devices comprising a gold anode;

FIG. 8a shows a plot of current density (mA/cm²) versus voltage (V) for devices of the invention comprising different thicknesses of protective charge transporting polymer layer and comparative devices comprising a gold anode;

FIG. 8b shows a plot of efficiency, measured as Lm/W, versus voltage (V) for devices of the invention comprising different thicknesses of protective charge transporting polymer layer and comparative devices comprising a gold anode;

FIG. 8c shows a plot of efficiency, measured as Cd/A, versus voltage (V) for devices of the invention comprising different thicknesses of protective charge transporting polymer layer and comparative devices comprising a gold anode;

FIG. 8d shows a plot of EQE versus voltage (V) for devices of the invention comprising different thicknesses of protective charge transporting polymer layer and comparative devices comprising a gold anode;

FIG. 8e shows a plot of luminance (cd/m²) versus time (hours) for devices of the invention comprising different thicknesses of protective charge transporting polymer layer and comparative devices comprising a gold anode;

FIG. 9a shows a plot of current density (mA/cm²) versus voltage for devices of the invention comprising a protective charge transporting polymer layer comprising a dopant and comparative devices comprising a gold anode;

FIG. 9b shows a plot of efficiency, measured as Lm/W, versus voltage (V) for devices of the invention comprising a protective charge transporting polymer layer comprising a dopant and comparative devices comprising a gold anode;

FIG. 9c shows a plot of efficiency, measured as Cd/A, versus voltage for devices of the invention comprising a protective charge transporting polymer layer comprising a dopant and comparative devices comprising a gold anode;

FIG. 9d shows a plot of EQE versus voltage (V) for devices of the invention comprising a protective charge transporting polymer layer comprising a dopant and comparative devices comprising a gold anode;

FIG. 9e shows a plot of luminance (cd/m²) versus time (hours) for devices of the invention comprising a protective charge transporting polymer layer comprising a dopant and comparative devices comprising a gold anode;

FIG. 10a is a schematic of the experimental set up used to measure the uniformity of light emission of devices of the invention and comparable devices comprising a gold anode or a copper anode rinsed with acetic acid, but lacking a protective charge transporting polymer layer;

FIG. 10b shows the results of testing for uniformity of light emission in devices comprising an unprotected copper anode (top row), a copper anode protected with a charge transporting polymer layer according to the invention (middle row) and a gold anode (bottom row);

FIG. 10c shows a plot of number of counts versus light intensity for devices comprising an unprotected copper anode and a copper anode protected with a charge transporting polymer layer according to the invention at 0 hours and after 40 or 70 hours of use.

### DETAILED DESCRIPTION OF THE INVENTION

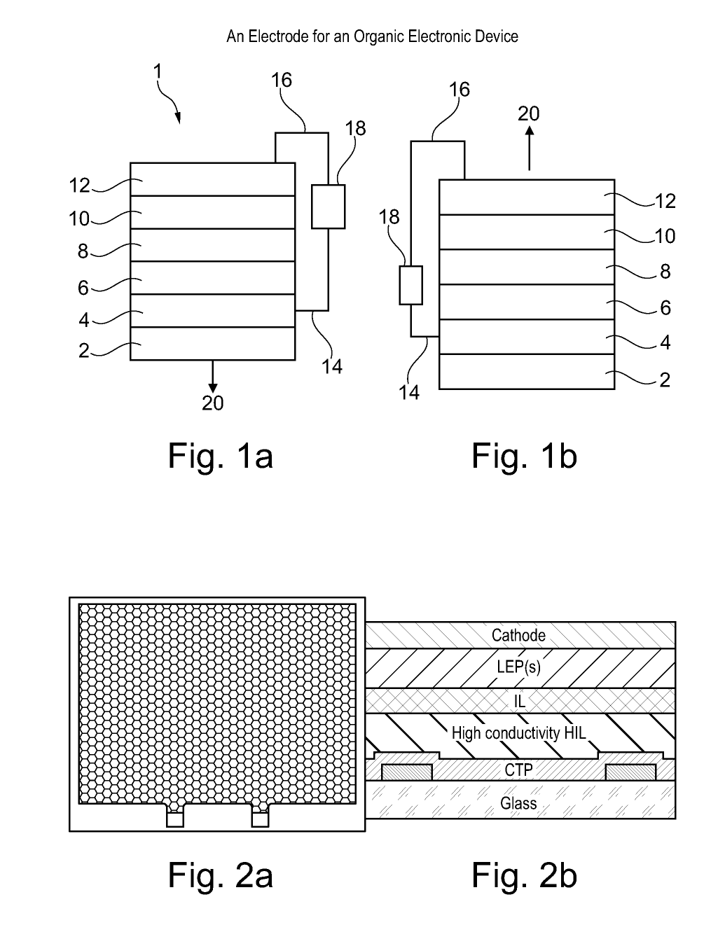

A cross-section through a basic structure of a typical OLED 1 is shown in FIG. 1a. A glass or plastic substrate 2 supports a transparent anode layer 4 comprising, for example, a charge transport polymer protected Cu grid on which is deposited a hole injection layer 6, a light emitting layer 8, an electron injection layer 10 and a cathode 12. The hole injection layer 6, which helps match the hole energy levels of the anode layer 4 and the light emitting layer 8, comprises a conductive transparent polymer. Cathode 12 comprises a trilayer of sodium fluoride, silver and aluminium. Contact wires 14 and 16 to the anode and the cathode respectively provide a connection to a power source 18.

In so-called “bottom emitter” devices, the multi-layer sandwich is deposited on the front surface of a planar glass substrate, with the reflecting electrode layer, usually the cathode, furthest away from the substrate, whereby light generated internally in the light emitting layer is coupled out of the device through the substrate. An example of a bottom emitter 1a is shown in FIG. 1a, where light 20 is emitted through transparent anode 4 and substrate 2 and the cathode 12 is reflective.

Conversely, in a so-called “top emitter”, the multi-layer sandwich is disposed on the back surface of the substrate 2, and the light generated internally in the light emitting layer 8 is coupled externally through a transparent electrode layer 12 without passing through the substrate 2. An example of a top emitter 1b is shown in FIG. 1b. Usually the transparent electrode layer 12 is the cathode, although devices which emit through the anode may also be constructed. The cathode layer 12 can be made substantially transparent by keeping the thickness of cathode layer less than around 50-100 nm, for example.

### EXAMPLES

### Materials

The substrate was soda lime glass obtained from Corning
The anode grid was copper. The copper was obtained from Leybold Sputter Target.
Six different protective charge transporting polymers were employed as follows: CTP1 comprises repeat units (A1), (B2), (B3) and (C4) described above. The ratio of the repeat units is 75% wt (A1), 5% wt (B2), 5% wt (B3) and 15% wt (C4)
CTP2 comprises repeat units (A1), (B2), (B3), (C3) and (C4) described above. The ratio of the repeat units is 30% wt (A1), 7.5% wt (B2), 7.5% (B3), 5% wt (C3) and 50% (C4).
CTP3 comprises repeat units (A1), (B2) and (B3) described above. The ratio of the repeat units is 90% wt (A1), 5% wt (B2) and 5% wt (B3).
CTP4 comprises repeat units (A4), (B1) and (C3) described above. The ratio of the repeat units is 42.5% wt (A4), 7.5% wt (B1) and 50% wt (C3).
CTP5 comprises repeat units (A3), (B2), (C3) and (C4) described above. The ratio of the repeat units is 30% wt (A3), 7.5% wt (B2), 12.5 5 wt (C3) and 50% (C4)
CTP6 comprises repeat units (A1), (B2), (B3), (C3) and (C4) described above. The ratio of the repeat units is 30% wt (A1), 5% wt (B2), 5 wt % (B3), 10% wt (C3) and 50% (C4).
All charge transporting polymers were polymerised by Suzuki polymerisation as described in WO0053656.
The dopant used was C₆₀F₃₆. This was prepared by the method described in WO2012/131314.
The hole injection layer (HIL) was high conductivity PEDOT:PSS obtained from Heraeus.
The interlayer polymer comprises repeat units (D), (A) and (B) described above. The ratio of the repeat units is 50% wt (Di), 42.5% wt (A1) and 7.5% wt (B1). It was polymerised by Suzuki polymerisation as described in WO0053656.
Two different light emitting layers were used as follows:
LEP1 is a multilayer device comprising a green light emitting layer, a combined red light emitting-triplet diffusion prevention layer and a combined blue light emitting-triplet control polymer layer. The green light emitting layer comprises a light emitting polymer comprising repeat units (D), (C), (E), (F) and (B). It comprises these repeat units in the ratio 50% wt (Di), 20.7% wt (C1), 11.5% wt (Eiii), 7.8% wt (Fiii), 5% wt (B2) and 5% wt (B3). The combined red light emitting-triplet diffusion prevention layer comprises a 50:50 mol % blend of two polymer blends. The first polymer blend comprises a first polymer and a red light emitting compound. The red light emitting compound is (Gi) as described in WO2009/157424. The ratio of components in the blend is 50% wt (Di), 36.5% wt (A1), 3.2% wt (C2), 10% wt (B2) and 0.6% wt (Gi). The second polymer blend comprises a second polymer and the red light emitting compound, (Gi). The ratio of components in the blend is 50% wt (Di), 22% wt (Eiii), 17.7% wt (C2), 10% wt (B2) and 0.6% wt (Gi). The combined blue light emitting-triplet control polymer layer comprises a 99:1 mol % blend of two polymers. The first polymer, representing the blue light emitting polymer, comprises 36% wt (C1), 45% wt (C2), 14% wt (C3), 4% wt (A2) and 1% wt (Ii). The second polymer, representing the triplet control polymer, comprises 50% wt (C5) and 50% wt (Ji). All polymers were polymerised by Suzuki polymerisation as described in WO0053656.
LEP2 is a green light emitting layer comprising a light emitting compound of formula (K) and a light emitting polymer comprising repeat units (D), (E) and (C). It comprises these repeat units in the ratio 50% wt (Di), 10% wt (Eiii) and 40% wt (C1). The ratio of light emitting compound to polymer is 30:70 by weight. The light emitting layer was polymerised by Suzuki polymerisation as described in WO0053656.
The cathode is NaF—Al—Ag. Sodium fluoride (in powder form), aluminium and silver wires were all obtained from Sigma Aldrich.

### Preparative Example for the Fabrication of a Protected Copper Anode

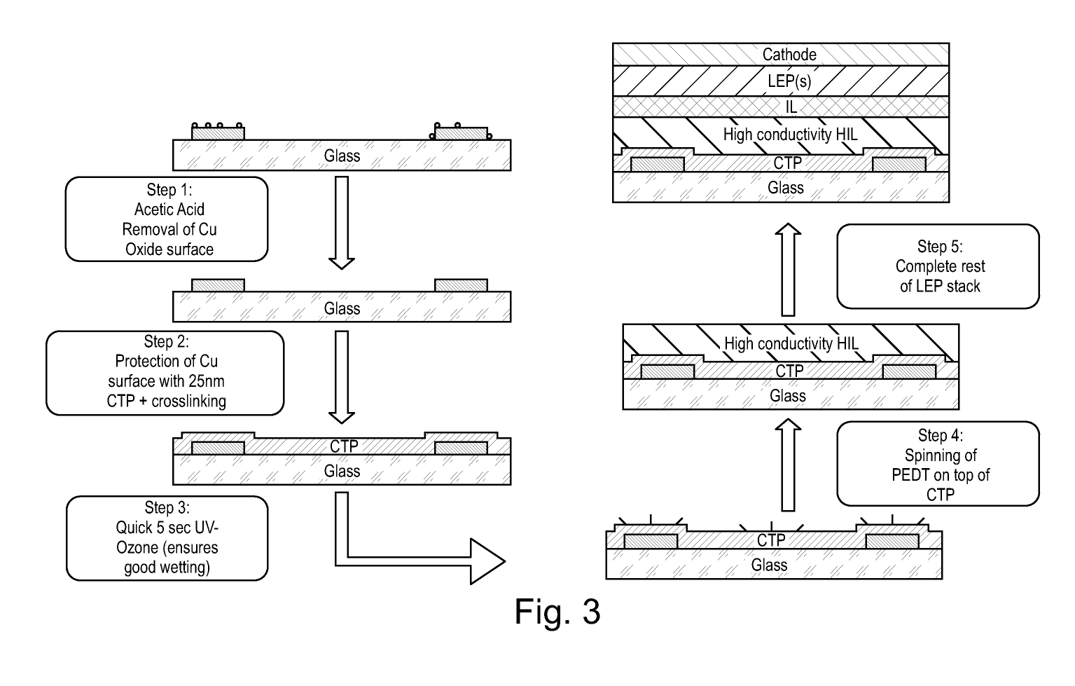

The process used is shown in FIG. 3. A Cu anodegrid was deposited, patterned and etched onto a soda lime glass substrate using conventional photolithographic techniques. The anode pattern is shown in FIG. 2a. The grid forms a honeycomb pattern.

The Cu grid was exposed for 2 minutes to UV ozone treatment, then with 2M acetic acid and heated to 60° C. for 1 minute to remove any CuO from the surface. The substrates were dried under N₂ and transferred into a glovebox (N₂ environment) and baked at 70° C. for 15 minutes. The protective charge transporting polymer was subsequently spin coated onto the Cu grid deposited on the substrate and baked in a glovebox. The different spin coating conditions used for the various protective charge transporting polymers used are shown in the table below.

| Protective charge | | Concentration of | |
|---|---|---|---|
| transporting | | interlayer polymer | Baking conditions - |
| polymer | Solvent | in solvent | (° C./mins) |
| CTP1 | o-xylene | 0.6 | 180/60 |
| CTP2 | aqueous | | 130/15 |
| CTP3 | o-xylene | 0.6 | 180/60 |
| CTP4 | o-xylene | 0.6 | 180/60 |
| CTP5 | o-xylene | 0.6 | 180/60 |
| CTP6 | o-xylene | 0.6 | 180/60 |

Prior to deposition of the HIL, i.e. PEDOT:PSS, the protective charge transporting polymer was subjected to a short (5 seconds) UV/Ozone treatment to ensure good wetting during spin coating. After this step, the usual OLED processing steps were followed as set out below.

### Preparative Example for the Fabrication of Organic Light Emitting Diodes

A device having the structure shown in FIG. 2b was prepared by the method described below. The preparative process used is set out in FIG. 3.

### (i) Spin Coating and Thernal Annealing of HIL

The HIL was deposited by spin-coating high conductivity PEDOT:PSS, available from Heraeus, from water in air to a thickness of 150 nm. The HIL was thermally annealed at 130° C. for 15 mins in air. Isolation of the HIL to the cathode contact areas was performed by swabbing the HIL with water.

### (ii) Spin Coating and Cross-Linking of IL

The interlayer was deposited by spin coating the interlayer polymer from a 0.6% wt concentration in o-xylene. The IL was thermally cross-linked at 180° C. for 60 minutes in a glove box with a nitrogen atmosphere and with low moisture levels. The final IL has a thickness of 22 nm.

(iii) Spin Coating of Light Emitting Layer

LEP1—the Different Layers of the Multi Layer Device were Spun Sequentially. Green Light Emitting Layer

This light emitting layer was deposited by spin coating the light emitting polymer, from a 0.7% wt solution in o-xylene. The green light emitting layer was dried at 180° C. for 60 minutes in a glove box. The final green light emitting layer has a thickness of 30 nm.

### Combined Red Light Emitting/Triplet Diffusion Prevention Layer

This light emitting layer was deposited by spin coating a 50:50 mol % blend of the two polymer blends, from a 0.6% wt solution in o-xylene. The light emitting layer was dried at 180° C. for 60 mins in a glove box. The final thickness of this light emitting layer was 20 nm.

### Combined Blue Light Emitting/Triplet Control Polymer Layer

This light emitting layer was deposited by spin coating a 99:1 mol % of the two polymers, from a 1% wt solution in o-xylene. The light emitting layer was dried at 130° C. for 10 minutes in a glove box. The final thickness of this light emitting layer was 50 nm.

LEP2

The green light emitting layer was deposited by spin coating a blend of the light emitting polymer(host) and light emitting compound, from a 2.0% wt solution in o-xylene. The green light emitting layer was dried at 180° C. for 60 minutes in a glove box. The final green light emitting layer has a thickness of 100 nm.

### (iv) Deposition of Cathode

The cathodes were blanket-deposited by successive thermal evaporation in a vacuum of successive layers of sodium fluoride (2 nm), aluminium (100 nm) and silver (100 nm) to give a trilayer NaF/A1/Ag cathode.

Two comparative devices were also prepared. These devices each have different anodes as described below, but are otherwise prepared by an identical process to that described above.

### Comparative Device 1: Cu Only

The anode in this device solely comprises Cu, i.e. it is not protected by a charge transporting polymer layer. In some experiments, where indicated, copper oxide present on the copper metal following deposition was removed by dilute acetic acid treatment prior to spinning of the HIL.

### Comparative Device 2: Au Only

The anode in this device is Au. Since Au does not form an oxide, it does not require protection. The use of gold in devices is, however, prohibitively expensive in most circumstances.

### Testing of OLED Device

Current, voltage, and luminance drive characteristics are collected for device performance screening using characterised silicon photodiodes and device spectral output characteristics collected using a calibrated spectrometer system and collection optics. The device is typically swept through a voltage range, and IVL data curves are collected, the condition, timings and parameters under which measurements are made are controlled. Refined drive characteristics are collected using traceably calibrated, industry standard, photometry, colour measurement systems, power supplies and meters.

Life time is screened using photodiode based measuring systems, these monitor the device luminance and applied voltage, while it being driven by calibrated power supplies under specified conditions (constant current). The environmental conditions under which tests are carried out are stringently controlled.

### Example 1

### Comparison of Cu Only and Au Only Devices

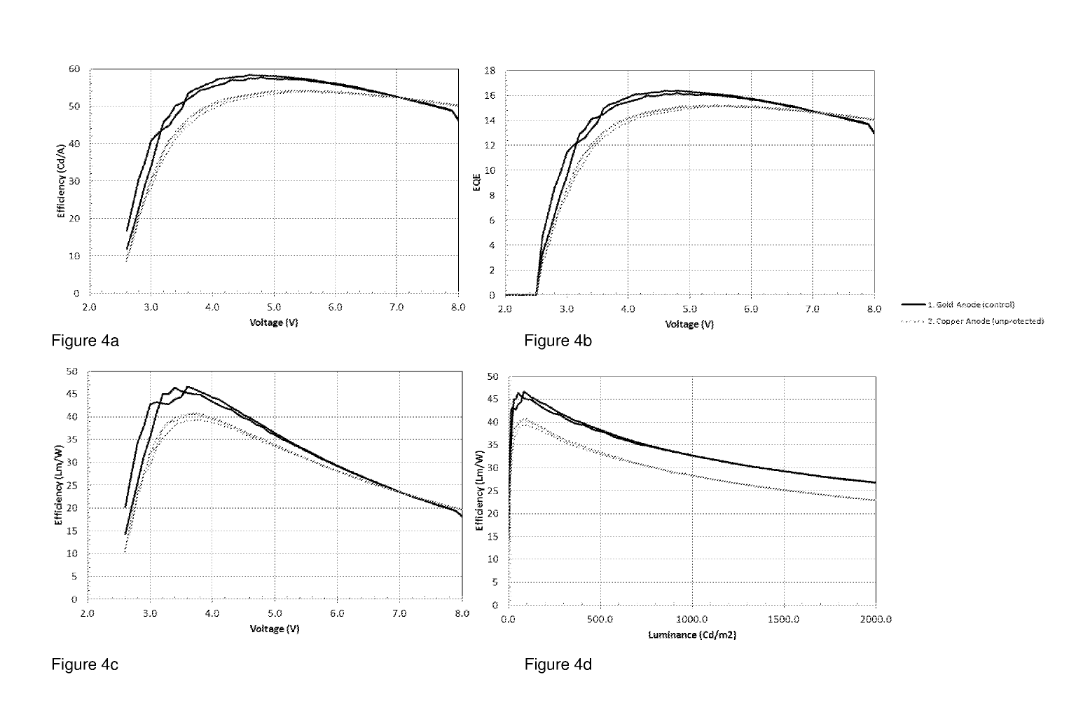

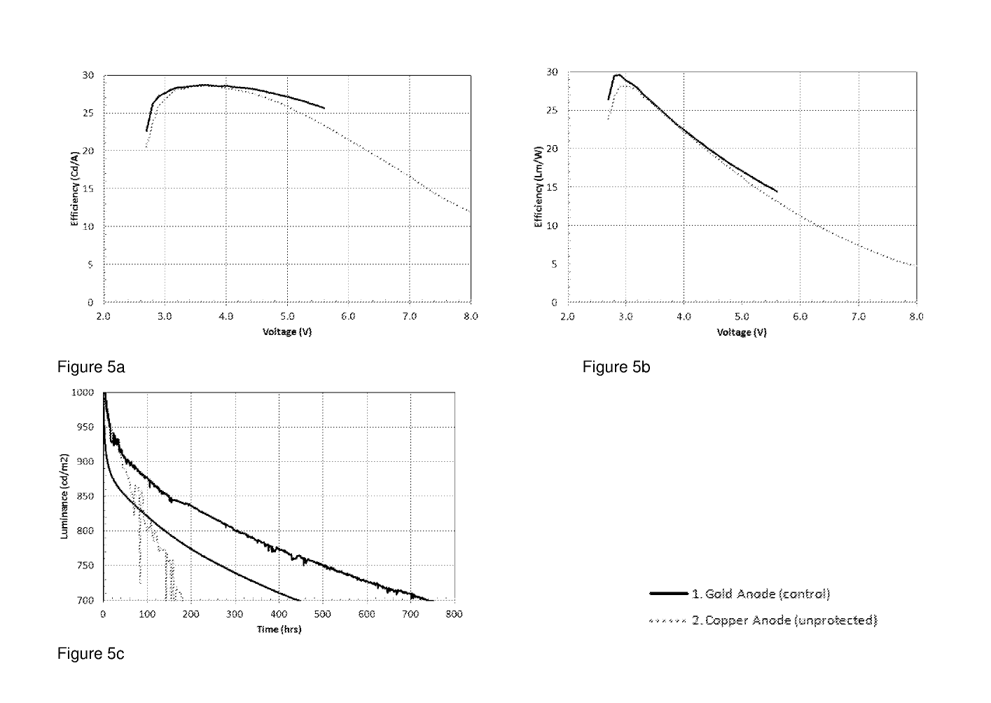

Comparable devices were prepared according to the above methods, wherein the light emitting layer was LEP1. The electrical performance of each of the devices is summarised in the table below and shown in FIGS. 4(a)-(d) (LEP2) and FIGS. 5(a)-(c) (LEP1).

| | | | Median | |
|---|---|---|---|---|
| | Median efficiency | Median | efficiency | |
| | (Cd/A) @ | EQE @ | (Lm/W) @ | Median |
| | 1000 | 1000 | 1000 | lifetime |
| Device | Cd/m² | Cd/m² | Cd/m² | (hrs) |
| Au only | 57.1 | 16.0 | 32.7 | |
| LEP2 | | | | |
| Cu only | 53.8 | 15.1 | 28.3 | |
| LEP2 | | | | |
| Au only | 27.9 | | 19.6 | 590 |
| LEP1 | | | | |
| Cu only | 18.4 | | 8.8 | 140 |
| LEP2 | | | | |

The results show that unprotected copper leads to a significant drop in device performance. Current density, EQE and Lm/W all drop significantly when Cu is used as an anode compared to the unreactive, but expensive, Au anode metal. In all cases the Cu devices short on lifetest very rapidly, and the Au devices live on to T70 in most cases.

### Example 2

### Impact of Acetic Acid Rinse Step

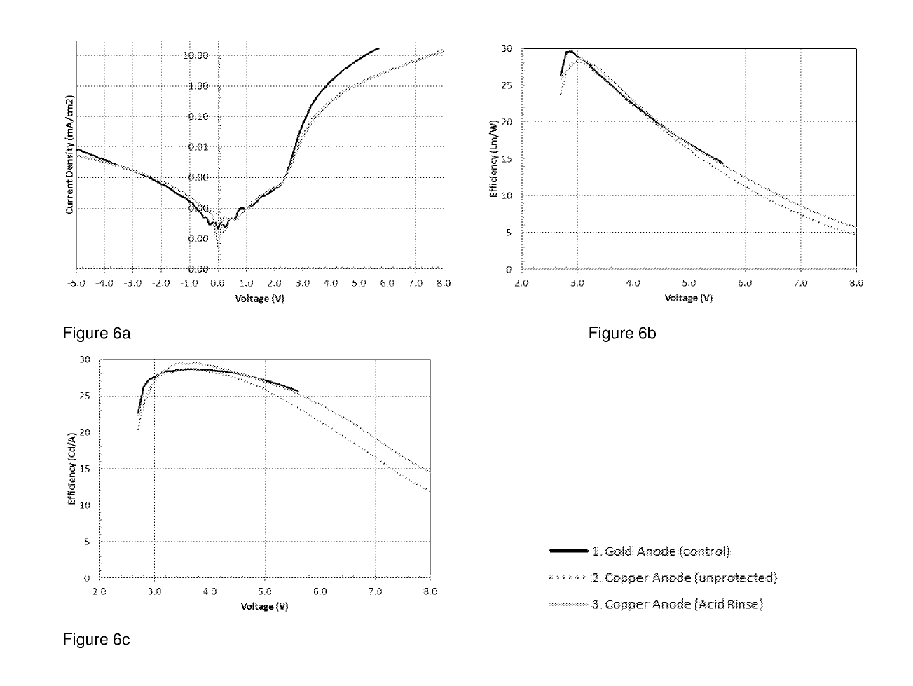

Comparable devices were prepared according to the above methods, wherein the light emitting layer was LEP1. An acetic acid rinse step was employed prior to deposition of the HIL. Thus the copper grid was treated with 2M acetic acid and heated to 60° C. for 1 minute to remove any CuO from the surface. The substrates were then dried under N₂ air and transferred into a glove box (N₂ environment) and baked at 70° C. for 15 minutes. The electrical performance of each of the devices is summarised in the table below and shown in FIGS. 6(a)-(c). The table additionally includes comparable data for the Cu only devices, i.e. devices wherein the acetic acid rinse step was not carried out as in example 1 above.

| | Median | Median | Median | Median |
|---|---|---|---|---|
| | voltage | current | efficiency | efficiency |
| | (V) @ | (mA/cm²) @ | (Cd/A) @ | (Lm/W) @ |
| | 1000 | 1000 | 1000 | 1000 |
| Device | Cd/m² | Cd/m² | Cd/m² | Cd/m² |
| Au only | 4.5 | 3.6 | 27.9 | 19.6 |
| Cu with acetic | 6.6 | 4.8 | 20.9 | 10.1 |
| acid rinse | | | | |
| Cu only | 6.7 | 5.4 | 18.4 | 8.8 |

The results show that the use of an acetic acid rinse during device fabrication improves electrical performance but that parity with Au is not achieved.

### Example 3

### Impact of Protective Charge Transporting Polymer Layer on the Cu Anode

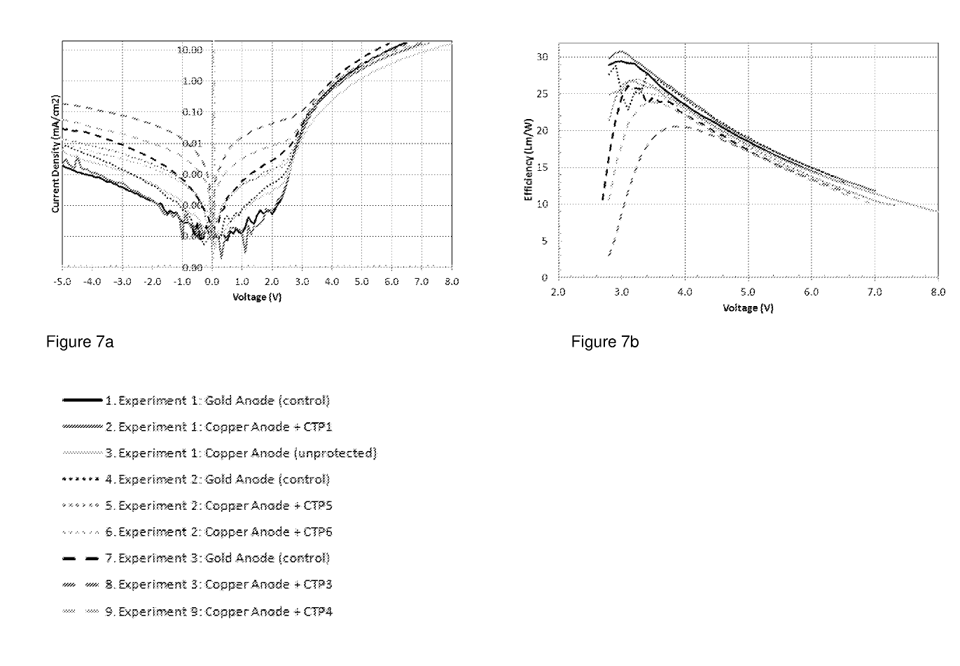

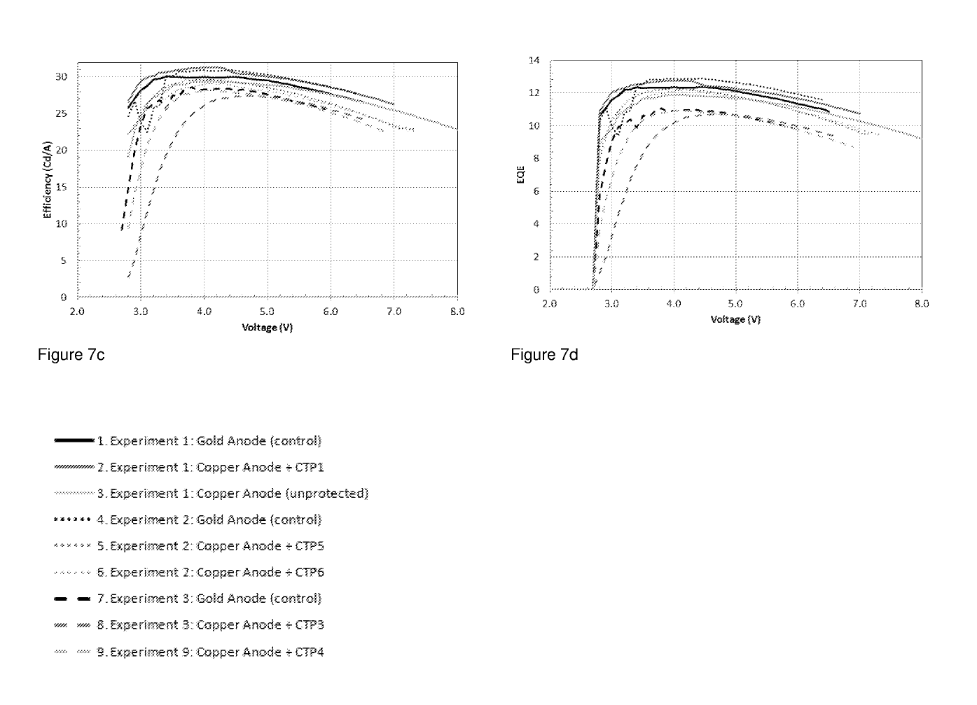

A series of three experiments were carried wherein comparable devices were prepared according to the above methods and as summarised in the table below. All protective charge transporting polymer layers had a thickness of 25 nm. An UV/ozone treatment and acetic acid rinse step were employed as described above prior to deposition of the HIL. The electrical performance of each group of devices is summarised in the table below and shown in FIGS. 7(a)-(d).

| | Protective | Median | Median | Median | Median | | |
|---|---|---|---|---|---|---|---|
| | charge | voltage | current | efficiency | efficiency | Median | |
| | transporting | (V) | (mA/cm²) | (Cd/A) | (Lm/W) | EQE | Median |
| | polymer | @ 1000 | @ 1000 | @ 1000 | @ 1000 | @ 1000 | lifetime |
| Anode | layer | Cd/m² | Cd/m² | Cd/m² | Cd/m² | Cd/m² | (hrs) |
| Au | — | 5.2 | 3.4 | 29.3 | 17.7 | 11.9 | 475 |
| Cu | CTP1 | 5.0 | 3.4 | 29.7 | 18.6 | 12.2 | 90 |
| Cu | — | 6.0 | 3.6 | 27.7 | 14.3 | 11.1 | |
| Au | — | 4.9 | 3.3 | 30.3 | 19.5 | 12.5 | |
| Cu | CTP5 | 5.2 | 3.6 | 27.9 | 16.7 | 11.6 | |
| Cu | CTP6 | 5.3 | 3.8 | 26.7 | 15.8 | 11.1 | |
| Au | — | 4.7 | 3.8 | 26.5 | 17.8 | 10.1 | |
| Cu | CTP3 | 5.1 | 4.0 | 25.2 | 15.8 | 9.4 | |
| Cu | CTP4 | 4.8 | 3.7 | 27.1 | 17.3 | 10.6 | |

The results show a significant improvement in performance compared to copper devices rinsed with acetic acid during processing. The results also show that a comparable electrical performance to gold is achieved. The lifetime and quality of the lifetime traces for the protected copper devices is significantly improved compared to unprotected copper but is not as a long as gold.

### Example 4

### Impact of Thickness of Protective Charge Transporting Polymer Layer on the Cu Anode

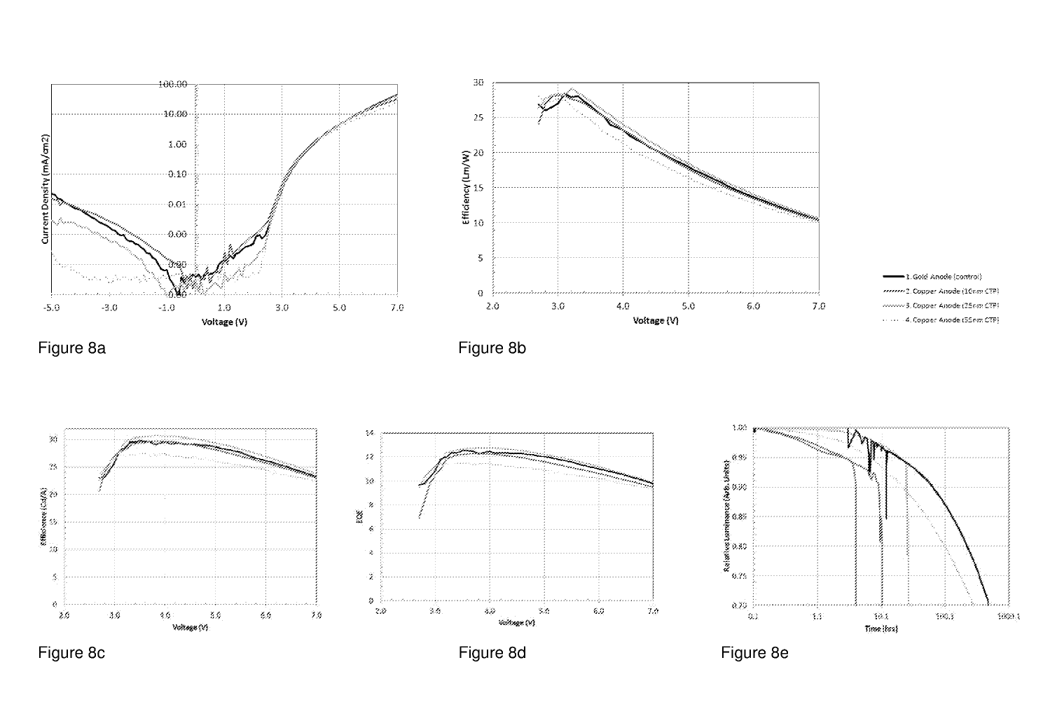

An experiment was carried out to investigate the effect of the thickness of the protective charge transporting polymer layer on device electrical performance and lifetime. Comparable devices were prepared according to the above methods and as summarised in the table below. All devices comprised protective charge transporting polymer layer (CTP6) in a thickness shown in the table below. An UV/ozone treatment and an acetic acid rinse step were employed prior to deposition of the HIL as described above. The electrical performance of the devices is summarised in the table below and shown in FIGS. 8(a)-(e).

| | Pro- | Me- | Me- | Median | Median | Me- | |
|---|---|---|---|---|---|---|---|
| | tective | dian | dian | effi- | effi- | dian | |
| | CTP | volt- | current | ciency | ciency | EQE | Me- |
| | layer | age | (mA/ | (Cd/A) | (Lm/W) | @ | dian |
| | Thick- | (V) @ | cm²) | @ | @ | @ | life- |
| | ness | 1000 | @ 1000 | 1000 | 1000 | 1000 | time |
| Anode | (nm) | Cd/m² | Cd/m² | Cd/m² | Cd/m² | Cd/m² | (hrs) |
| Au | — | 4.9 | 4.1 | 24.4 | 15.5 | 10.0 | 475 |
| Cu | 25 | 4.9 | 4.3 | 23.2 | 15.0 | 9.8 | 10 |
| Cu | 55 | 5.2 | 4.7 | 21.2 | 12.9 | 8.9 | — |
| Cu | 10 | 5.0 | 4.2 | 23.6 | 14.2 | 9.6 | 275 |

The results show that a reasonably comparable electrical performance is achieved with the protective charge transporting polymer layers of different thicknesses. The optimum performance is achieved with 25 nm thickness.

### Example 5

### Impact of Doped Protective Charge Transporting Polymer Layer on the Cu Anode

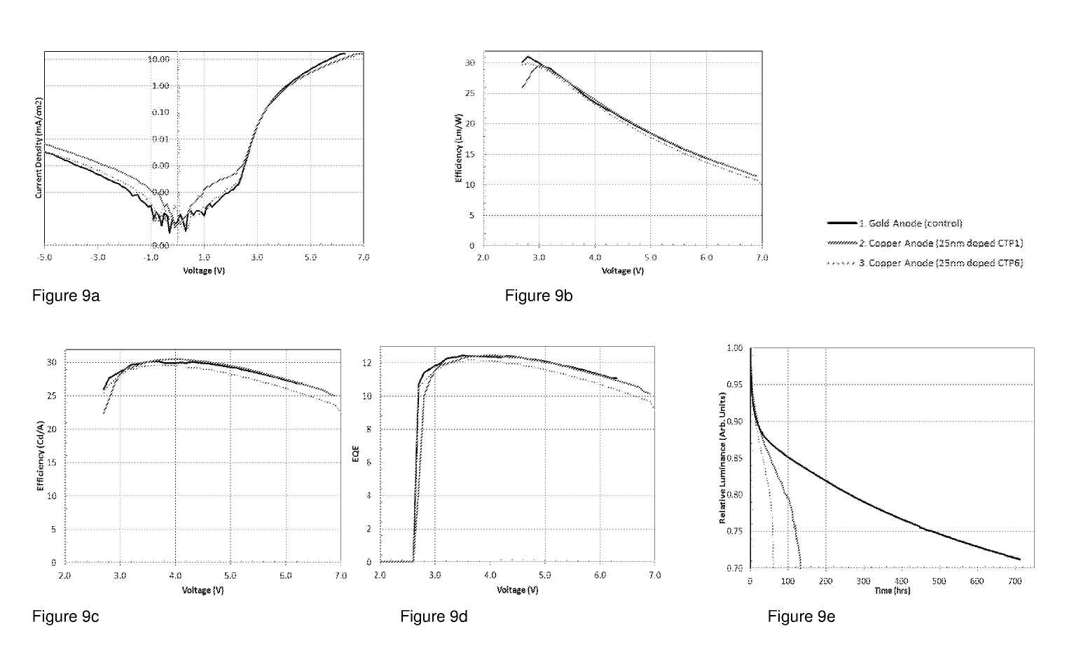

An experiment was carried out to investigate the effect of doping the protective charge transporting polymer layer. The dopant used was C₆₀F₃₀. 15.45% wt dopant was added to the solution of protective charge transporting polymer layer and spin coated onto the copper grid. Comparable devices were prepared according to the above methods and as summarised in the table below. An UV ozone treatment and an acetic acid rinse step was employed prior to deposition of the HIL as described above. The electrical performance of the devices is summarised in the table below and shown in FIGS. 9(a)-(e).

| | | Me- | Me- | Median | Me- | | |
|---|---|---|---|---|---|---|---|
| | | dian | dian | effi- | dian | Me- | |
| | | volt- | current | ciency | effi- | dian | Me- |
| | | age | (mA/ | (Cd/A) | ciency | EQE | dian |
| | Protective | (V) @ | cm²⁾ | @ | (Lm/W) | @ | life- |
| | CTP | 1000 | @ 1000 | 1000 | @ 1000 | 1000 | time |
| Anode | layer | Cd/m² | Cd/m² | Cd/m² | Cd/m² | Cd/m² | (hrs) |
| Au | — | 4.9 | 3.4 | 29.6 | 19.1 | 12.2 | 770 |
| Cu | CTP1 | 5.1 | 3.5 | 28.9 | 18.0 | 11.9 | 130 |
| | C₆₀F₃₀ | | | | | | |
| Cu | CTP6 | 5.1 | 3.6 | 27.8 | 17.8 | 11.5 | 60 |
| | C₆₀F₃₀ | | | | | | |

The results show that the provision of a doped protective charge transporting polymer layer leads to a significant performance boost compared to unprotected copper devices and in fact that performance to Au, control, devices is almost matched.

### Example 6

### Uniformity of Light Emission Over Time

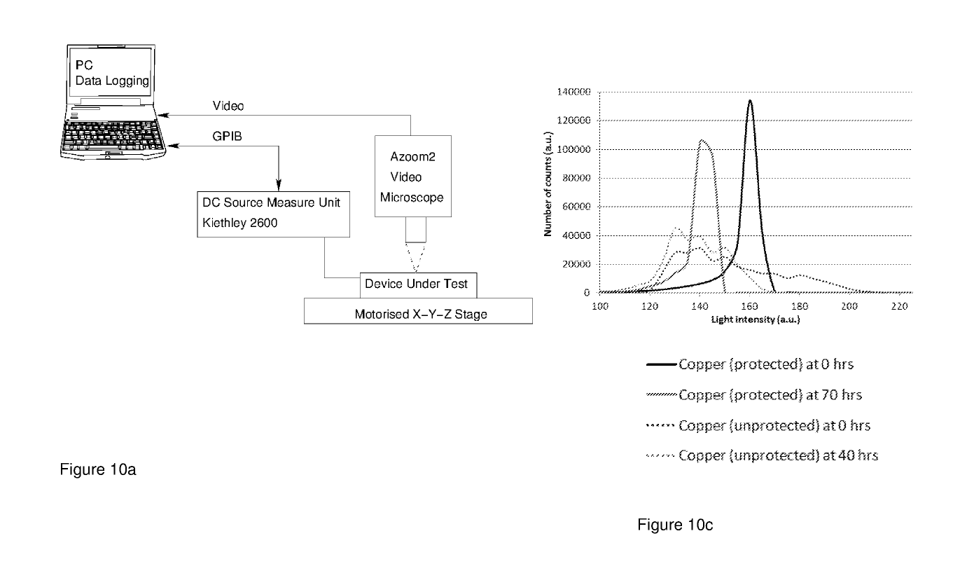

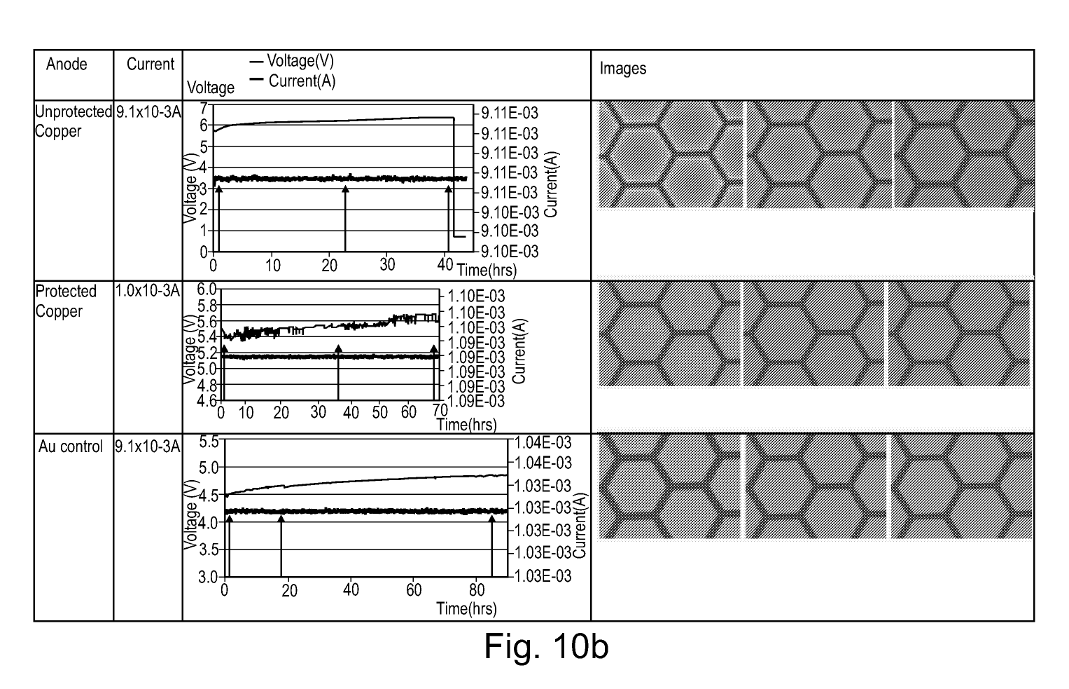

The set up used to carry out this test is shown in FIG. 10a. The technique enables pictures to be taken of devices during lifetime testing using a microscope. Images are converted to greyscale and a distribution of emission is calculated across the entire measurement area. More specifically a PC running labview controls a video microscope and a dc source measuring unit. The labview control program I-V logs data and triggers micrograph image capture if the device power changes or if a specified delay time has been exceeded. Analysis of the device output distribution is performed offline in Matlab.

Using this system, comparable devices comprising each of an Au anode, an unprotected Cu anode rinsed with acetic acid and a Cu anode protected with CTP4 were assessed. The results are shown in FIGS. 10b and 10c. The images shown on the right in FIG. 10b are taken at the time points indicated by the arrows from left to right. In the images for the unprotected copper, there is broadening of the non-emission zone immediately prior to a shorting event. In the image for the protected copper, it can be seen that a slight voltage rise and slight colour shift occurs with time, but there is no evidence of a change of grid width or uniformity of emission. In the images for the gold control, there is a slight voltage rise and colour change, as with the protected copper.

FIG. 10c shows the light emission distribution at different time points for the copper only anode and the Cu anode protected by the charge transporting polymer layer. The Cu only has a larger emission distribution, with a bright edge near the metal. The bright edge changes during use. The protected copper anode has a more uniform light emission distribution and a more uniform drop in emission. There is no bright edge observed.

1. A layered structure for an organic electronic device comprising:
(i) a substrate;
(ii) an electrode deposited on said substrate; and
(iii) a hole injection layer deposited on said electrode, wherein said electrode comprises:
(a) a metal grid; and
(b) an organic charge transporting polymer layer, wherein said organic charge transporting polymer layer and said substrate
encapsulate said metal grid.

2. The layered structure as claimed in claim 1, wherein said electrode is transparent to visible light.

3. The layered structure as claimed in claim 1, wherein said grid forms a honeycomb pattern.

4. The layered structure as claimed in claim 1, wherein said metal is copper.

5. The layered structure as claimed in claim 1, wherein said organic charge transporting polymer layer comprises at least one repeat unit comprising an amine group.

6. The layered structure as claimed in claim 1, wherein said organic charge transporting polymer layer comprises at least one repeat unit comprising a cross-linkable group.

7. The layered structure as claimed in claim 1, wherein said organic charge transporting polymer layer comprises at least one repeat unit selected from formula (C) below: 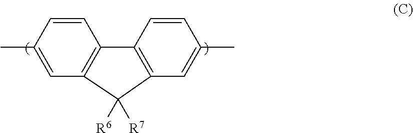
wherein R⁶ and R⁷ are independently selected from the group consisting of hydrogen, unsubstituted or substituted C₁₋₁₆ alkyl, wherein one or more non-adjacent C atoms are optionally replaced with O, S, N, CO, or —COO—, unsubstituted or substituted C₁₋₁₆ alkoxy, unsubstituted or substituted C₅₋₁₄ aryl, unsubstituted or substituted arylalkyl, unsubstituted or substituted C₅₋₁₄ heteroaryl, and unsubstituted or substituted heteroarylalkyl.

8. The layered structure as claimed in claim 1, wherein said organic charge transporting polymer layer further comprises a dopant.

9. The layered structure as claimed in claim 1, wherein said metal grid comprises a conductive track having a width of 10 to 100 microns.

10. The layered structure as claimed in claim 1, wherein said organic charge transporting polymer layer has a thickness of 5 nm to 100 nm.

11. An organic electronic device comprising a layered structure comprising:
(i) a substrate;
(ii) an electrode deposited on said substrate; and
(iii) a hole injection layer deposited on said electrode, wherein said electrode comprises:
(a) a metal grid; and
(b) an organic charge transporting polymer layer, wherein said organic charge transporting polymer layer and said substrate encapsulate said metal grid.

12. The organic electronic device as claimed in claim 11, wherein said device is an OLED lighting tile.

13. The organic electronic device as claimed in claim 11, wherein said electrode is an anode, and wherein said device further comprises
at least one light emitting layer and
a cathode.

14. A method of making a layered structure as claimed in claim 1, comprising:
(i) depositing said metal grid on said substrate;
(ii) depositing said organic charge transporting polymer layer on said metal grid; and
(iii) depositing said hole injection layer on at least one surface of said organic charge transporting polymer layer.

15. A method of making an organic electronic device comprising making a layered structure comprising:
(i) a substrate;
(ii) an electrode deposited on said substrate; and
(iii) a hole injection layer deposited on said electrode, wherein said electrode comprises:
(a) a metal grid; and
(b) an organic charge transporting polymer layer, wherein said organic charge transporting polymer layer and said substrate encapsulate said metal grid.
